(19) United States
(12) Patent Application Publication
(10) Pub. No.: US 2026/0329174 A1
(43) Pub. Date: Oct. 22, 2026

(54) SEMICONDUCTOR SUBSTRATE MANUFACTURING METHOD, AND RESIST UNDERLAYER FILM FORMING COMPOSITION

(71) Applicant: JSR CORPORATION, Tokyo (JP)

(72) Inventors: Masato DOBASHI, Tokyo (JP); Shunpei AKITA, Tokyo (JP); Satoshi DEI, Tokyo (JP); Yuya HAYASHI, Tokyo (JP); Hiroyuki MIYAUCHI, Tokyo (JP); Kazunori TAKANASHI, Tokyo (JP); Kazuya TAKADA, Tokyo (JP); Tatsuya KASAI, Tokyo (JP)

(73) Assignee: JSR CORPORATION, Tokyo (JP)

(21) Appl. No.: 19/463,312

(22) Filed: Jan. 29, 2026

Related U.S. Application Data
(63) Continuation-in-part of application No. PCT/JP2024/026067, filed on Jul. 22, 2024.

(30) Foreign Application Priority Data
Aug. 2, 2023 (JP) 2023-126477

(51) Int. Cl. G03F 7/004; G03F 7/11; G03F 7/20; H10P 50/00; H10P 76/20

(52) U.S. Cl. CPC G03F 7/0042; G03F 7/11; G03F 7/2004; H10P 50/692; H10P 50/695; H10P 76/2041

(57) ABSTRACT

A method for manufacturing a semiconductor substrate includes applying a composition directly or indirectly to a substrate to form a resist underlayer film. The composition includes a polymer including: a repeating unit (1) including an organic sulfonic acid anion moiety and an onium cation moiety; a repeating unit (2) represented by formula (2); and a repeating unit (3) represented by formula (3). In the formula (2), R⁴ is a group selected from the group consisting of groups represented by formulas (2-1) to (2-8). In the formula (3), R⁶ is a group comprising a partial structure represented by formula (3-1) or (3-2). In the formulas (3-1) and (3-2), X¹ and X² are each independently an oxygen atom, a sulfur atom, or a nitrogen atom.

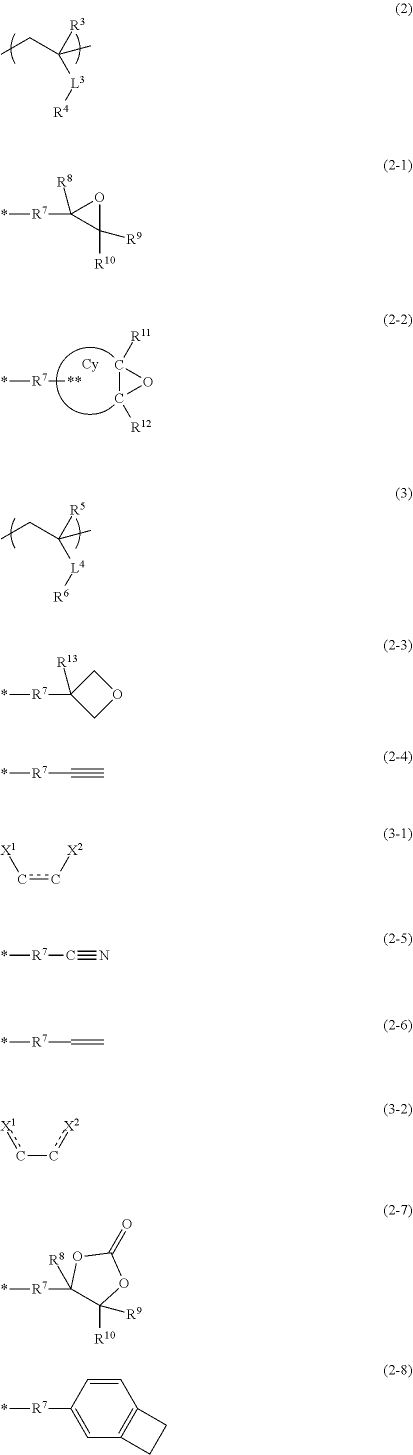

### CROSS-REFERENCE TO RELATED APPLICATIONS

The present application is a continuation-in-part application of International Patent Application No. PCT/JP2024/026067 filed Jul. 22, 2024, which claims priority to Japanese Patent Application No. 2023-126477 filed Aug. 2, 2023. The contents of these applications are incorporated herein by reference in their entirety.

### BACKGROUND OF THE DISCLOSURE

### Technical Field

The present invention relates to a method for manufacturing a semiconductor substrate and a composition for forming a resist underlayer film.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film in such EUV exposure (see WO 2013/141015 A).

As resist patterns formed by exposure to extreme ultraviolet light and development become increasingly finer, there is a demand for pattern rectangularity that suppresses pattern tailing at the bottom of the resist film and ensures rectangularity of the resist pattern.

### SUMMARY

According to an aspect of the present disclosure, a method for manufacturing a semiconductor substrate includes: applying a composition directly or indirectly to a substrate to form a resist underlayer film; forming a resist film on the resist underlayer film; exposing the resist film to radiation; and developing the exposed resist film. The composition includes: a polymer (hereinafter also referred to as “polymer [A]”); and a solvent (hereinafter also referred to as “solvent [C]”. The polymer includes: a repeating unit (1) including an organic sulfonic acid anion moiety and an onium cation moiety; a repeating unit (2) represented by formula (2); and a repeating unit (3) represented by formula (3).

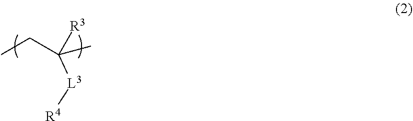

In the formula (2), R³ is a hydrogen atom or a substituted or unsubstituted monovalent hydrocarbon group having 1 to 20 carbon atoms; L³ is a single bond or a divalent linking group; R⁴ is a group selected from the group consisting of groups represented by formulas (2-1) to (2-8).

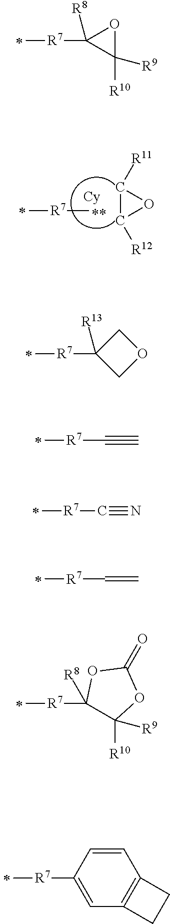

In the formulas (2-1) to (2-3) and (2-7), R⁸, R⁹, R¹⁰, R¹², and R¹³ are each independently a hydrogen atom or a monovalent organic group having 1 to 20 carbon atoms; in the formula (2-2), Cy is a ring structure having 3 to 20 ring members constituted together with the two carbon atoms in the formula; R¹¹ is a hydrogen atom, a monovalent organic group having 1 to 20 carbon atoms, or a single bond; ** is a bond to an atom constituting Cy; provided that when R¹¹ is a single bond, R¹¹ is bonded to **; in the formulas (2-1) to (2-8), R⁷ is a divalent organic group having 1 to 20 carbon atoms or a single bond; * is a bond to an atom constituting L³.

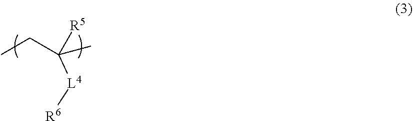

In the formula (3), R⁵ is a hydrogen atom or a substituted or unsubstituted monovalent hydrocarbon group having 1 to 20 carbon atoms; L⁴ is a single bond or a divalent linking group; R⁶ is a group comprising a partial structure represented by formula (3-1) or (3-2).

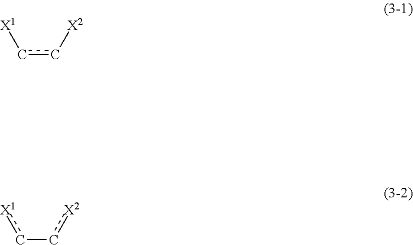

In the formulas (3-1) and (3-2), X¹ and X² are each independently an oxygen atom, a sulfur atom, or a nitrogen atom; each
[symbol] independently represents a single bond or a double bond; provided that the formula (3-1) is excluded from a definition of the formula (3-2).

According to another aspect of the present disclosure, a resist underlayer film forming composition includes: a polymer; and a solvent. The polymer includes: a repeating unit (1) including an organic sulfonic acid anion moiety and an onium cation moiety; a repeating unit (2) represented by formula (2); and a repeating unit (3) represented by formula (3).

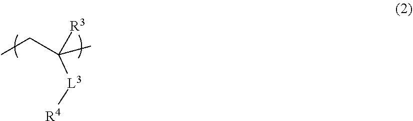

In the formula (2), R³ is a hydrogen atom or a substituted or unsubstituted monovalent hydrocarbon group having 1 to 20 carbon atoms; L³ is a single bond or a divalent linking group; R⁴ is a group selected from the group consisting of groups represented by formulas (2-1) to (2-8).

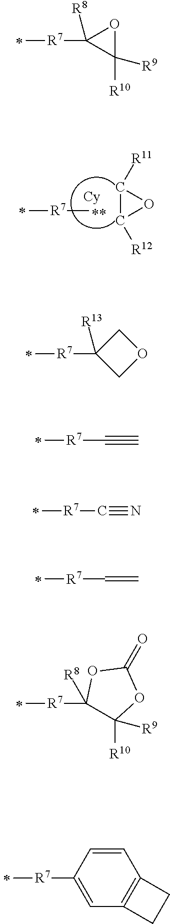

In the formulas (2-1) to (2-3) and (2-7), R⁸, R⁹, R¹⁰, R¹², and R¹³ are each independently a hydrogen atom or a monovalent organic group having 1 to 20 carbon atoms; in the formula (2-2), Cy is a ring structure having 3 to 20 ring members constituted together with the two carbon atoms in the formula; R¹¹ is a hydrogen atom, a monovalent organic group having 1 to 20 carbon atoms, or a single bond; ** is a bond to an atom constituting Cy; provided that when R¹¹ is a single bond, R¹¹ is bonded to **; in the formulas (2-1) to (2-8), R⁷ is a divalent organic group having 1 to 20 carbon atoms or a single bond; * is a bond to an atom constituting L³.

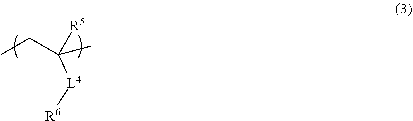

In the formula (3), R⁵ is a hydrogen atom or a substituted or unsubstituted monovalent hydrocarbon group having 1 to 20 carbon atoms; L⁴ is a single bond or a divalent linking group; R⁶ is a group comprising a partial structure represented by formula (3-1) or (3-2).

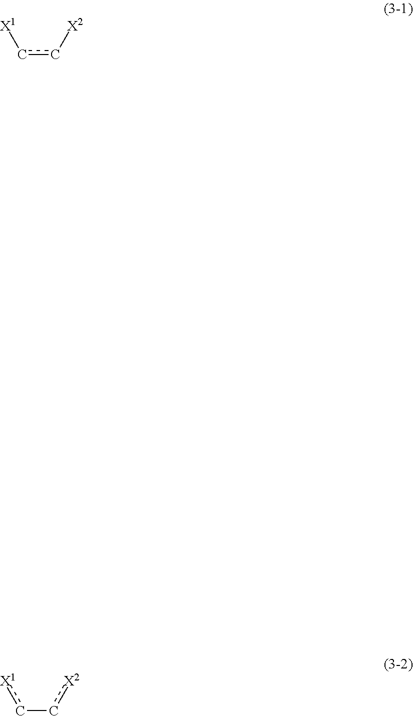

In the formulas (3-1) and (3-2), X¹ and X² are each independently an oxygen atom, a sulfur atom, or a nitrogen atom; each
[symbol] independently represents a single bond or a double bond; provided that the formula (3-1) is excluded from a definition of the formula (3-2).

### DETAILED DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In the present specification, the “number of ring members” refers to the number of atoms forming a ring regardless of whether the ring is a monocyclic ring or a polycyclic ring. The number of ring members is, for example, 5 for tetrahydrofuran, 6 for benzene, 10 for adamantane, 10 for quinoline, 12 for biphenyl, and 13 for fluorene.

According to the method for manufacturing a semiconductor substrate, it is possible to efficiently manufacture a semiconductor substrate due to the use of a composition for forming a resist underlayer film capable of forming a resist underlayer film that can impart excellent pattern rectangularity to a resist pattern. According to the composition for forming a resist underlayer film, it is possible to form a resist underlayer film that can impart excellent pattern rectangularity to a resist pattern. Therefore, they can suitably be used for, for example, manufacturing semiconductor devices expected to be further microfabricated in the future.

Hereinafter, a method for manufacturing a semiconductor substrate and a composition for forming a resist underlayer film according to each embodiment of the present invention will be described in detail. Combinations of suitable modes in the embodiments are also preferred.

### <<Method for Manufacturing Semiconductor Substrate>>

The method for manufacturing a semiconductor substrate includes applying a composition for forming a resist underlayer film directly or indirectly to a substrate (hereinafter also referred to as “step of applying a composition for forming a resist underlayer film”); forming a resist film on a resist underlayer film formed by the step of applying a composition for forming a resist underlayer film (hereinafter also referred to as “resist film forming step”); exposing the resist film to radiation (hereinafter also referred to as “exposing step”); and developing at least the exposed resist film (hereinafter also referred to as “developing step”).

According to the method for manufacturing a semiconductor substrate, it is possible to form a resist underlayer film that can impart excellent pattern rectangularity to a resist pattern due to the use of the prescribed composition for forming a resist underlayer film in the step of applying a composition for forming a resist underlayer film, so that it is possible to manufacture a semiconductor substrate having a favorable pattern shape.

The method for manufacturing a semiconductor substrate may further include, as necessary, a step of forming an organic underlayer film directly or indirectly on the substrate (hereinafter also referred to as “organic underlayer film forming step”) before the step of applying a composition for forming a resist underlayer film.

Hereinafter, the composition for forming a resist underlayer film to be used in the method for manufacturing a semiconductor substrate, and the respective steps in the case of including the organic underlayer film forming step, which is an optional step, will be described.

### <Composition for Forming Resist Underlayer Film>

The composition for forming a resist underlayer film (hereinafter also referred to as “composition”) includes a polymer [A] and a solvent [C]. The composition may contain any optional component as long as the effect of the present disclosure is not impaired. The composition for forming a resist underlayer film can form a resist underlayer film that can impart excellent pattern rectangularity to a resist pattern owing to including the polymer [A] and the solvent [C].

### <Polymer [A]>

The polymer [A] contains a repeating unit (1), a repeating unit (2), and a repeating unit (3). The polymer [A] may contain other repeating units in addition to these repeating units. The polymer [A] may have one type or two or more types of each of the repeating unit (1), the repeating unit (2), and the repeating unit (3). The composition may contain one type or two or more types of the polymer [A]. The polymer [A] is preferably an acrylic polymer.

### (Repeating Unit (1))

The repeating unit (1) has an organic sulfonic acid anion moiety and an onium cation moiety. The organic sulfonic acid anion moiety and the onium cation moiety form an onium salt structure, and an acid (sulfonic acid) is generated through exposure to light. The form of containing the organic sulfonic acid anion moiety and the onium cation moiety is not particularly limited, and the organic sulfonic acid anion moiety may be bonded to the polymer chain of the polymer [A], and the onium cation moiety may be contained as a counter ion thereof, or the onium cation moiety may be bonded to the polymer chain of the polymer [A], and the organic sulfonic acid anion moiety may be contained as a counter ion thereof.

When the polymer [A] is an acrylic polymer, the repeating unit (1) is preferably a repeating unit represented by the following formula (1-1) or (1-2) (hereinafter, each of them is also referred to as “repeating unit (1-1)” or the like).

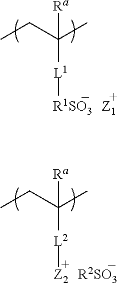

In the formula (1-1), R^{a} is a hydrogen atom or a substituted or unsubstituted monovalent hydrocarbon group having 1 to 20 carbon atoms; L¹ is a divalent linking group; R¹ is a single bond or a divalent organic group having 1 to 40 carbon atoms; and Z₁⁺ is a monovalent onium cation,
in the formula (1-2), R^{a} and L² have the same meanings as R^{a} and L¹ in the formula (1-1), respectively; Z₂⁺ is a monovalent group having a monovalent onium cation structure; and R² is a monovalent organic group having 1 to 40 carbon atoms.

In the repeating unit (1-1), an organic sulfonic acid anion moiety (—R¹SO₃—) is bonded to a polymer chain (side chain) of the polymer [A], and an onium cation moiety (Z₁⁺) is contained as a counter ion thereof. In the repeating unit (1-2), an onium cation moiety (—Z₂⁺) is bonded to a polymer chain (side chain) of the polymer [A], and an organic sulfonic acid anion moiety (R²SO₃) is contained as a counter ion thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent hydrocarbon group having 1 to 20 carbon atoms represented by R^{a} in the formulas (1-1) and (1-2) include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include alkyl groups such as a methyl group, an ethyl group, a n-propyl group, an isopropyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

When R¹ has a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group.

Among them, a hydrogen atom or a methyl group is preferable as R^{a} from the viewpoint of the copolymerizability of a monomer that affords the repeating unit (1).

In the formulas (1-1) and (1-2), as the divalent linking group represented by L¹ and L², for example, a divalent hydrocarbon group, —COO—, —OCO—, —O—CO—O—, —CONH—, —O—, —S—, —CO—, or a group obtained by combining these groups can be suitably employed.

As the divalent hydrocarbon group as L¹ and L², a group obtained by removing one hydrogen atom from the monovalent hydrocarbon group having 1 to 20 carbon atoms represented by R^{a} can be suitably employed. Among them, L¹ and L² preferably contain a divalent aromatic ring, and more preferably contain a benzenediyl group or a naphthalenediyl group.

Examples of the divalent organic group having 1 to 40 carbon atoms represented by R¹ in the formula (1-1) include groups obtained by removing one hydrogen atom from any of the monovalent organic groups having 1 to 40 carbon atoms represented by R² in the formula (1-2). Therefore, first, the monovalent organic group having 1 to 40 carbon atoms represented by R² in the formula (1-2) will be described. In the present specification, the “organic group” refers to a group containing at least one carbon atom.

Examples of the monovalent organic group having 1 to 40 carbon atoms represented by R² in the formula (1-2) include a monovalent hydrocarbon group having 1 to 40 carbon atoms, a group having a divalent hetero atom-containing linking group between two adjacent carbon atoms or at a carbon chain end of the foregoing hydrocarbon group, and a group obtained by replacing some or all of the hydrogen atoms of the foregoing hydrocarbon group with a monovalent hetero atom-containing substituent, and a group obtained by combining them.

As the monovalent hydrocarbon group having 1 to 40 carbon atoms, groups obtained by extending the monovalent hydrocarbon groups having 1 to 20 carbon atoms represented by R^{a} to 40 carbon atoms can be suitably employed.

Examples of the hetero atom that constitutes the divalent hetero atom-containing linking group or monovalent hetero atom-containing substituent include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing linking group include —CO—, —CS—, —NR′—, —O—, —S—, —SO₂—, and groups obtained by combining them. R′ is a hydrogen atom or a hydrocarbon group having 1 to 10 carbon atoms.

Examples of the monovalent heteroatom-containing substituent include a hydroxy group, a sulfanyl group, a cyano group, a nitro group, and a halogen atom.

The organic sulfonic acid anion moiety containing R² is preferably represented by the following formula (p-1). In the formula (p-1), a moiety excluding a sulfonate ion (SO₃—) corresponds to R².

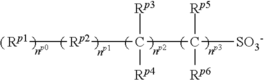

in the formula (p-1), R^{p1} is a monovalent group containing a 5- or higher-membered ring structure;
R^{p2} is a divalent organic group;
R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms;
R^{p5} and R^{p6} are each independently a fluorine atom or a monovalent fluorinated hydrocarbon group having 1 to 20 carbon atoms;
n^{p0} is an integer of 0 to 2, n^{p1} is an integer of 0 to 10, n^{p2} is an integer of 0 to 10, and n^{p3} is an integer of 0 to 10, provided that n^{p0}+n^{p1}+n^{p2}+n^{p3} is an integer of 1 or more and 30 or less;
when n^{p1} is 2 or more, the plurality of R^{p2}s are identical or different from each other;
when n^{p2} is 2 or more, the plurality of R^{p3}s are identical or different from each other, and the plurality of R^{p4}s are identical or different from each other;
when n^{p3} is 2 or more, the plurality of R^{p5}s are identical or different, and the plurality of R^{p6}s are identical or different; and
Z⁺ is a monovalent onium cation.

Examples of the monovalent group containing a ring structure represented by R^{p1} include a monovalent group containing an alicyclic structure having 5 or more ring members, a monovalent group containing an aliphatic heterocyclic structure having 5 or more ring members, a monovalent group containing an aromatic ring structure having 6 or more ring members, and a monovalent group containing an aromatic heterocyclic structure having 6 or more ring members.

Examples of the alicyclic structure having 5 or more ring members include:
monocyclic cycloalkane structures such as a cyclopentane structure, a cyclohexane structure, a cycloheptane structure, a cyclooctane structure, a cyclononane structure, a cyclodecane structure, and a cyclododecane structure;
monocyclic cycloalkene structures such as a cyclopentene structure, a cyclohexene structure, a cycloheptene structure, a cyclooctene structure, and a cyclodecene structure;
polycyclic cycloalkane structures such as a norbornane structure, an adamantane structure, a tricyclodecane structure, and a tetracyclododecane structure; and
polycyclic cycloalkene structures such as a norbornene structure and a tricyclodecene structure.

Examples of the aliphatic heterocyclic structure having 5 or more ring members include:
lactone structures such as a pentanolactone structure, a hexanolactone structure, and a norbornane lactone structure;
sultone structures such as a pentanosultone structure, a hexanosultone structure, and a norbornane sultone structure;
oxygen atom-containing heterocyclic structures such as an oxacyclopentane structure, an oxacycloheptane structure, and an oxanorbornane structure;
nitrogen atom-containing heterocyclic structures such as an azacyclopentane structure, an azacyclohexane structure, and a diazabicyclooctane structure; and
sulfur atom-containing heterocyclic structures such as a thiacyclopentane structure, a thiacyclohexane structure, and a thianorbornane structure.

Examples of the aromatic ring structure having 6 or more ring members include a benzene structure, a naphthalene structure, a phenanthrene structure, and an anthracene structure.

Examples of the aromatic heterocyclic structure having 6 or more ring members include oxygen atom-containing heterocyclic structures such as a furan structure, a pyran structure, and a benzopyran structure, and nitrogen atom-containing heterocyclic structures such as a pyridine structure, a pyrimidine structure, and an indole structure.

The lower limit of the number of the ring members of the ring structure of R^{p1} may be 6, and is preferably 7, more preferably 8, still more preferably 9, and particularly preferably 10. The upper limit of the number of the ring members is preferably 15, more preferably 14, still more preferably 13, and particularly preferably 12.

Some or all of the hydrogen atoms which the ring structure of R^{p1} has may be replaced with a substituent. Examples of the substituent include halogen atoms such as a fluorine atom, a chlorine atom, a bromine atom, and an iodine atom, a hydroxy group, a carboxy group, a cyano group, a nitro group, an alkoxy group, an alkoxycarbonyl group, an alkoxycarbonyloxy group, an acyl group, an acyloxy group, and an oxo group (═O). Among them, a hydroxy group and an alkoxy group are preferable.

Among them, monovalent groups containing an alicyclic structure having 5 or more ring members and monovalent groups containing an aliphatic heterocyclic structure having 5 or more ring members are preferable as R^{p1}, monovalent groups containing an alicyclic structure having 6 or more ring members and monovalent groups containing an aliphatic heterocyclic structure having 6 or more ring members are more preferable, monovalent groups containing an alicyclic structure having 9 or more ring members and monovalent groups containing an aliphatic heterocyclic structure having 9 or more ring members are still more preferable, an adamantyl group, a hydroxyadamantyl group, a norbornane lactone-yl group, a norbornane sultone-yl group, and a 5-oxo-4-oxatricyclo[4.3.1.1^{3′8}]undecane-yl group are still more preferable, and an adamantyl group is particularly preferable.

As the divalent organic group represented by R^{p2}, the divalent organic group having 1 to 40 carbon atoms represented by R¹ in the above formula (1-1) can be suitably used. Among them, examples of the divalent organic group represented by R^{p2} include a carbonyl group, an ether group, a carbonyloxy group, a sulfide group, a thiocarbonyl group, a sulfonyl group, a divalent hydrocarbon group, or a combination thereof. As the divalent linking group represented by R^{p2}, a carbonyloxy group, a sulfonyl group, alkanediyl groups, and cycloalkanediyl groups are preferable, a carbonyloxy group and cycloalkanediyl groups are more preferable, a carbonyloxy group and a norbornanediyl group are still more preferable, and a carbonyloxy group is particularly preferable.

Examples of the monovalent hydrocarbon groups having 1 to 20 carbon atoms represented by R^{p3} and R^{p4} include alkyl groups having 1 to 20 carbon atoms. Examples of the monovalent fluorinated hydrocarbon groups having 1 to 20 carbon atoms represented by R^{p3} and R^{p4} include fluorinated alkyl groups having 1 to 20 carbon atoms. As R^{p3} and R^{p4}, a hydrogen atom, a fluorine atom, and fluorinated alkyl groups are preferable, a fluorine atom and perfluoroalkyl groups are more preferable, and a fluorine atom and a trifluoromethyl group are still more preferable.

Examples of the monovalent fluorinated hydrocarbon groups having 1 to 20 carbon atoms represented by R^{p5} and R^{p6} include fluorinated alkyl groups having 1 to 20 carbon atoms. As R^{p5} and R^{p6}, a fluorine atom and fluorinated alkyl groups are preferable, a fluorine atom and perfluoroalkyl groups are more preferable, a fluorine atom and a trifluoromethyl group are still more preferable, and a fluorine atom is particularly preferable.

n^{p0} is preferably 0 or 1.

As n^{p1}, integers of 0 to 5 are preferable, integers of 0 to 3 are more preferable, integers of 0 to 2 are still more preferable, and 0 or 1 is particularly preferable.

As n^{p2}, integers of 0 to 2 are more preferable, 0 or 1 is still more preferable, and 0 is particularly preferable.

As n^{p3}, integers of 0 to 5 are preferable, integers of 1 to 4 are more preferable, integers of 1 to 3 are still more preferable, and 1 or 2 is particularly preferable. By setting n^{p3} to be 1 or more, the strength of the acid generated from the compound of the formula (p-1) can be increased, and as a result, the rectangularity of a resist pattern can be further improved. The upper limit of n^{p3} is preferably 4, more preferably 3, and still more preferably 2.

In the formula (p-1), n^{p0}+n^{p1}+n^{p2}+n^{p3} is an integer of 1 or more and 30 or less. The lower limit of n^{p0}+n^{p1}+n^{p2}+n^{p3} is preferably 2, and more preferably 4. The upper limit of n^{p0}+n^{p1}+n^{p2}+n^{p3} is preferably 20, and more preferably 10.

Examples of the organic sulfonic acid anion moiety containing R¹ represented by the formula (p-1) include structures represented by the following formulas (p-1-1) to (p-1-53).

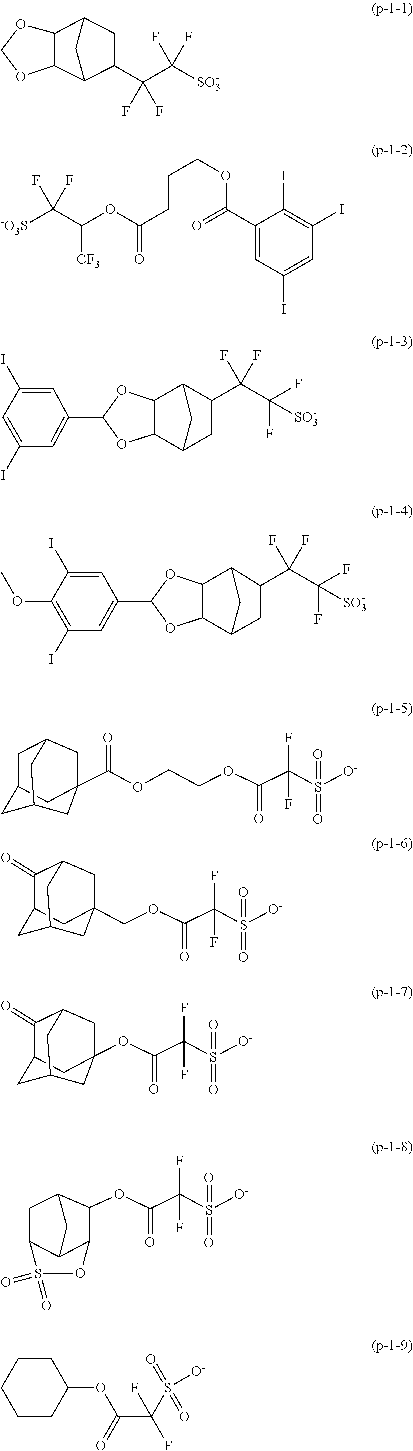

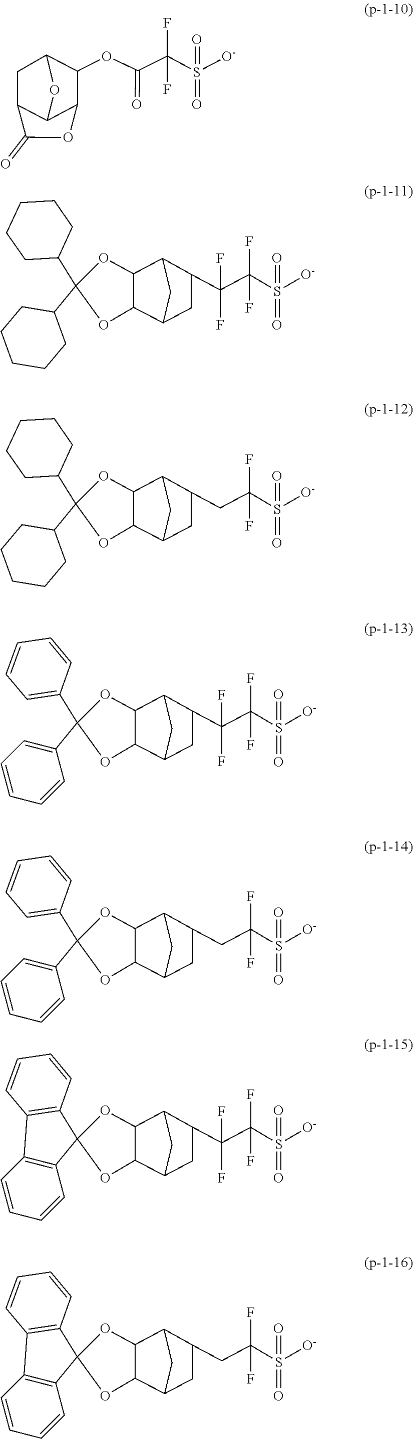

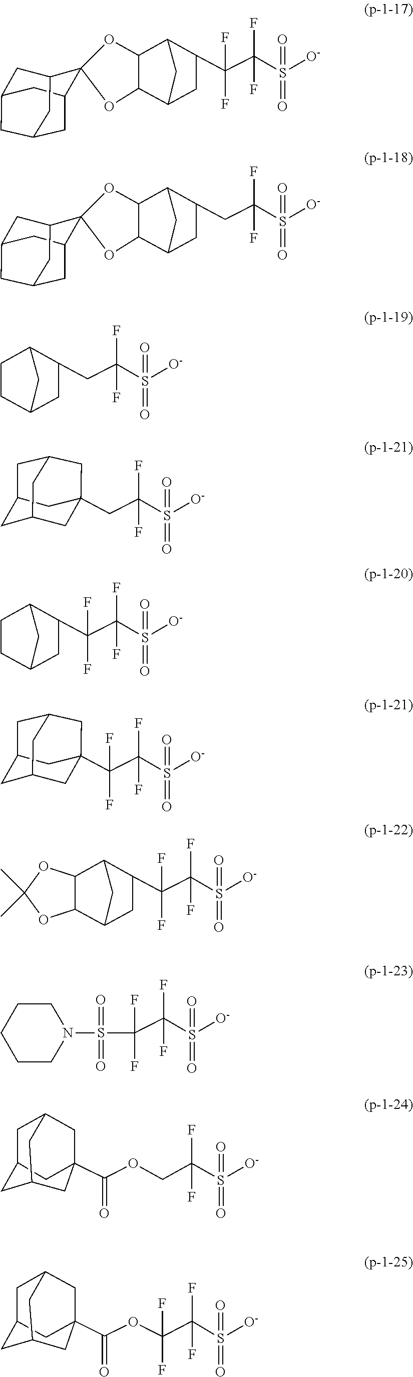

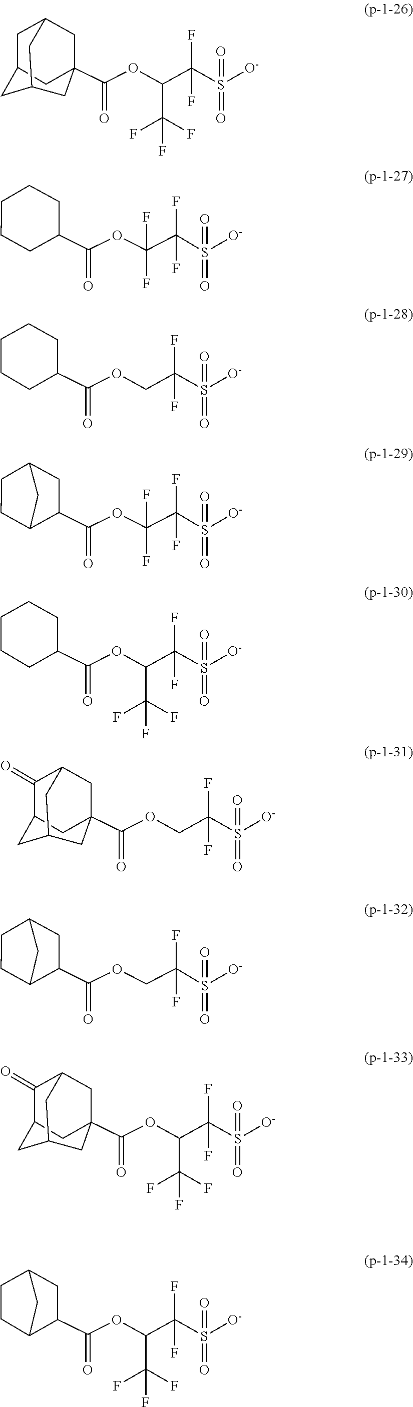

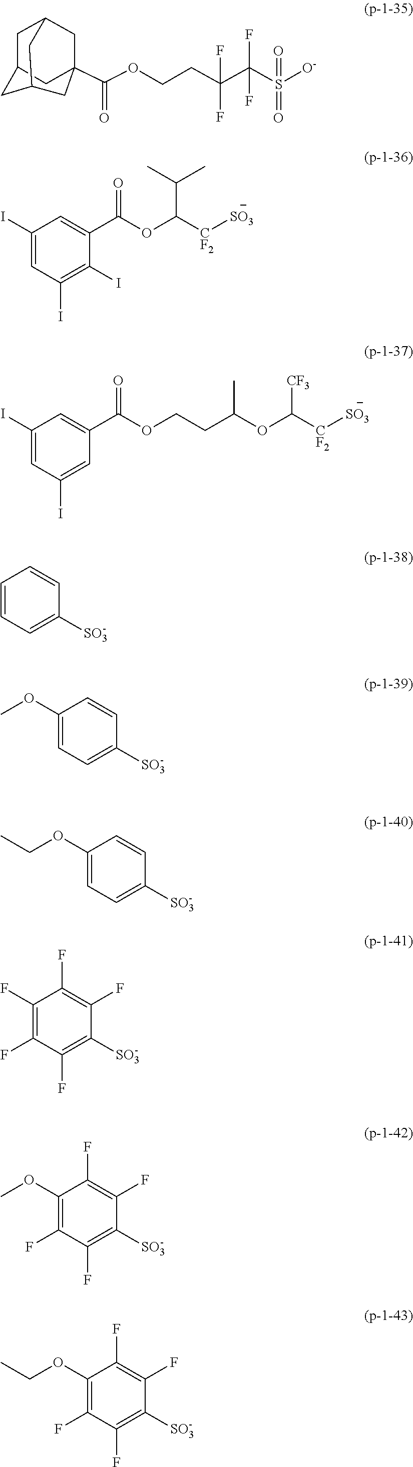

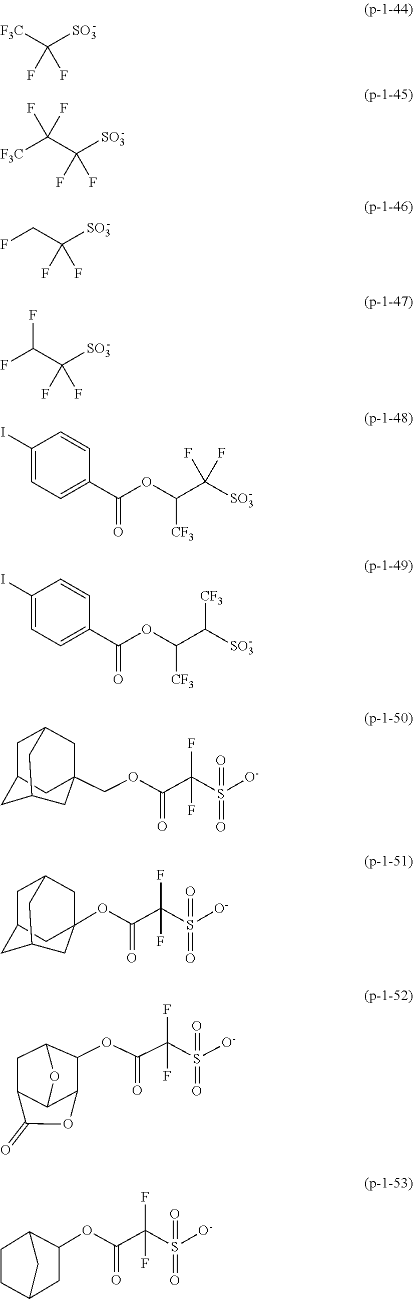

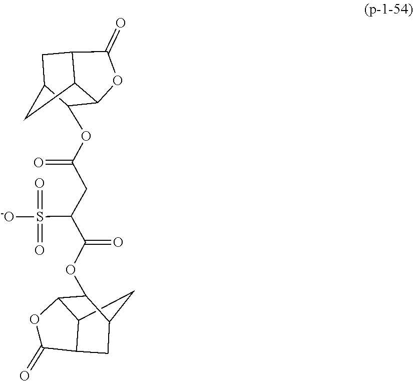

As described above, the divalent organic group having 1 to 40 carbon atoms represented by R¹ in the formula (1-1) corresponds to a structure obtained by removing one hydrogen atom or fluorine atom from the monovalent organic group having 1 to 40 carbon atoms represented by R² in the formula (1-2).

Examples of the monovalent onium cation represented by Z₁⁺ include radiolytic onium cations containing elements such as S, I, O, N, P, Cl, Br, F, As, Se, Sn, Sb, Te, and Bi, and examples thereof include a sulfonium cation, a tetrahydrothiophenium cation, an iodonium cation, a phosphonium cation, a diazonium cation, and a pyridinium cation. Among these examples, a sulfonium cation or an iodonium cation is preferable. The sulfonium cation or the iodonium cation is preferably represented by the following formulas (X-1) to (X-6).

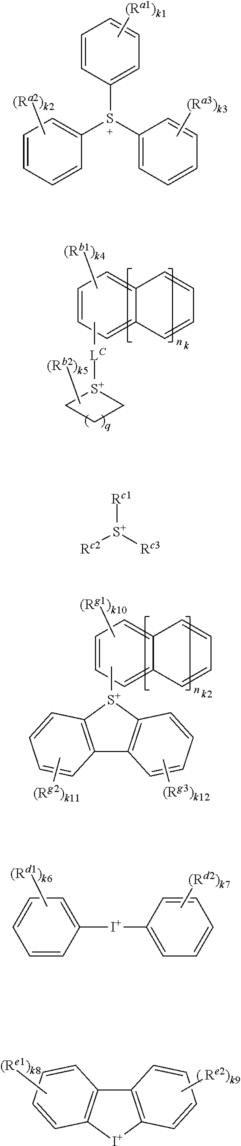

In the formula (X-1), R^{a1}, R^{a2}, and R^{a3} are each independently a substituted or unsubstituted, linear or branched, alkyl, alkoxy, or alkoxycarbonyloxy group having 1 to 12 carbon atoms, a substituted or unsubstituted, monocyclic or polycyclic cycloalkyl group having 3 to 12 carbon atoms, a substituted or unsubstituted aromatic hydrocarbon group having 6 to 12 carbon atoms, a hydroxy group, a halogen atom, —OSO₂—R^{P}, —SO₂—R^{Q}, or —S—R^{T}, or represent a ring structure in which two or more of these groups are combined with each other. The ring structure may contain a hetero atom such as 0 or S between two adjacent carbon atoms forming the skeleton. RP, R^{Q}, and R^{T} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. k1, k2, and k3 are each independently an integer of 0 to 5. When there are pluralities of R^{a1}s to R^{a3}s, R^{P}s, R^{Q}s, and R^{T}s, the pluralities of R^{a1}s to R^{a3}s, R^{P}s, R^{Q}s, and R^{T}s each may be either identical or different.

In the formula (X-2), R^{b1} is a substituted or unsubstituted, linear or branched, alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ is 0, k4 is an integer of 0 to 4, and when nₖ is 1, k4 is an integer of 0 to 7. When there are a plurality of R^{b1}s, the plurality of R^{b1}s may be identical or different, and the plurality of R^{b1} may represent a ring structure constituted by combining them with each other. R^{b2} is a substituted or unsubstituted, linear or branched alkyl group having 1 to 7 carbon atoms or a substituted or unsubstituted aromatic hydrocarbon group having 6 or 7 carbon atoms. L^{c} is a single bond or a divalent linking group. k5 is an integer of 0 to 4. When there are a plurality of R^{b2}s, the plurality of R^{b2}s may be identical or different, and the plurality of R^{b2}s may represent a ring structure constituted by combining them with each other. q is an integer of 0 to 3. In the formula, the ring structure containing S⁺ may contain a hetero atom such as 0 or S between two adjacent carbon atoms forming the skeleton.

In the above formula (X-3), R^{c1}, R^{c2}, and R^{c3} each independently are substituted or unsubstituted, linear or branched alkyl groups having 1 to 12 carbon atoms.

In the formula (X-4), R^{g1} is a substituted or unsubstituted, linear or branched, alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ₂ is 0, k10 is an integer of 0 to 4, and when nₖ₂ is 1, k10 is an integer of 0 to 7. When there are a plurality of R^{g1}s, the plurality of R^{g1}s may be identical or different, and the plurality of R^{g1} may represent a ring structure constituted by combining them with each other. R^{g2} and R^{g3} are each independently a substituted or unsubstituted, linear or branched, alkyl, alkoxy, or alkoxycarbonyloxy group having 1 to 12 carbon atoms, a substituted or unsubstituted, monocyclic or polycyclic cycloalkyl group having 3 to 12 carbon atoms, a substituted or unsubstituted aromatic hydrocarbon group having 6 to 12 carbon atoms, a hydroxy group, or a halogen atom, or represent a ring structure in which these groups are combined with each other. k1l and k12 are each independently an integer of 0 to 4. When there are pluralities of R^{g2}s and R^{g3}s, the pluralities of R^{g2}s and R^{g3}s may be identical or different, respectively.

In the formula (X-5), R^{d1} and R^{d2} each independently represent a substituted or unsubstituted, linear or branched, alkyl, alkoxy, or alkoxycarbonyl group having 1 to 12 carbon atoms, a substituted or unsubstituted aromatic hydrocarbon group having 6 to 12 carbon atoms, a halogen atom, a halogenated alkyl group having 1 to 4 carbon atoms, or a nitro group, or represent a ring structure constituted by combining two or more of these groups with each other. k6 and k7 each independently are an integer of 0 to 5. When there are pluralities of R^{d1}s and R^{d2}s, the pluralities of R^{d1}s and R^{d2}s may be identical or different, respectively.

In the above formula (X-6), R^{e1} and R^{e2} each independently are a halogen atom, a substituted or unsubstituted linear or branched alkyl group having 1 to 12 carbon atoms, or a substituted or unsubstituted aromatic hydrocarbon group having 6 to 12 carbon atoms. k8 and k9 each independently are an integer of 0 to 4.

Examples of the onium cation include, but not limited thereto, structures represented by the following formulas (i-2-1) to (i-2-47).

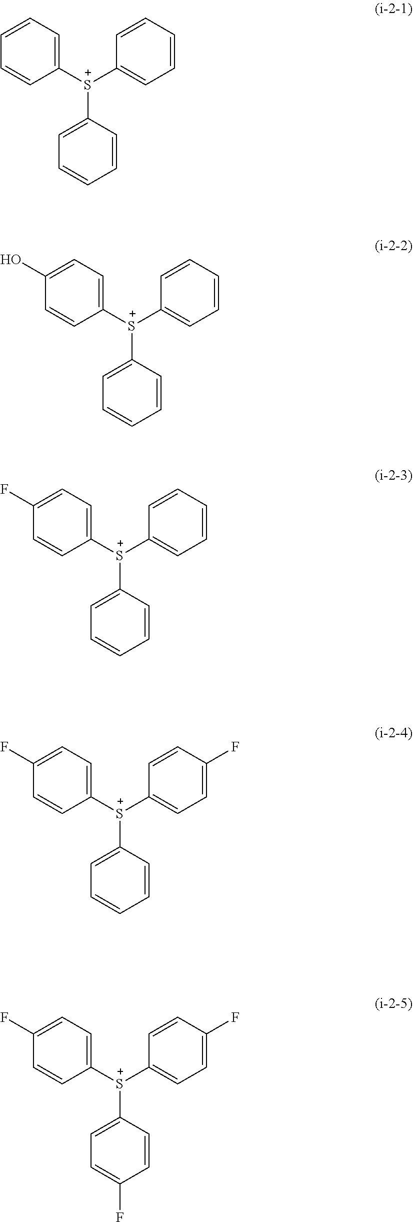 [SMILES: c1ccc([S+](c2ccccc2)c2ccccc2)cc1 ; Oc1ccc([S+](c2ccccc2)c2ccccc2)cc1 ; Fc1ccc([S+](c2ccccc2)c2ccccc2)cc1 ; Fc1ccc([S+](c2ccccc2)c2ccc(F)cc2)cc1 ; Fc1ccc([S+](c2ccc(F)cc2)c2ccc(F)cc2)cc1]

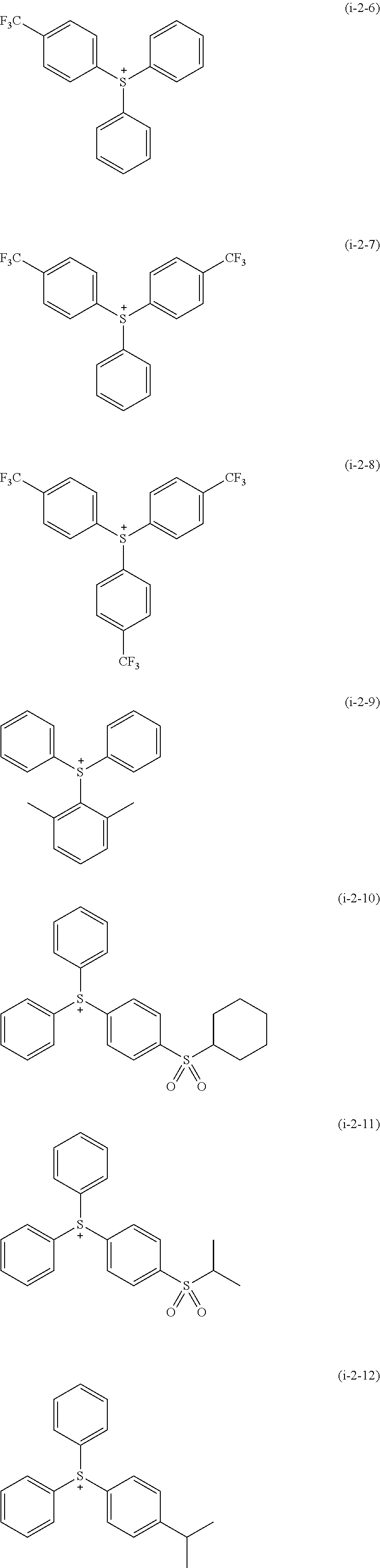

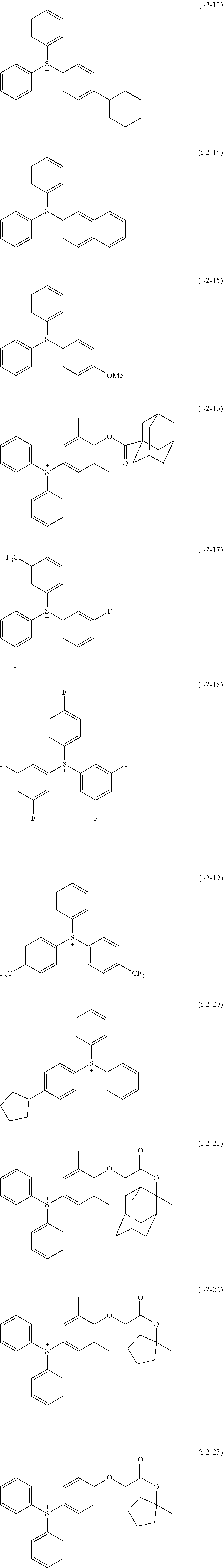

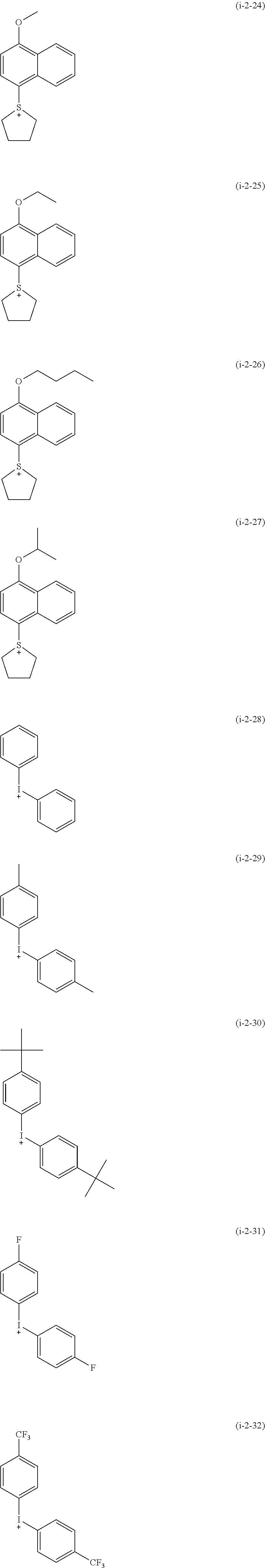

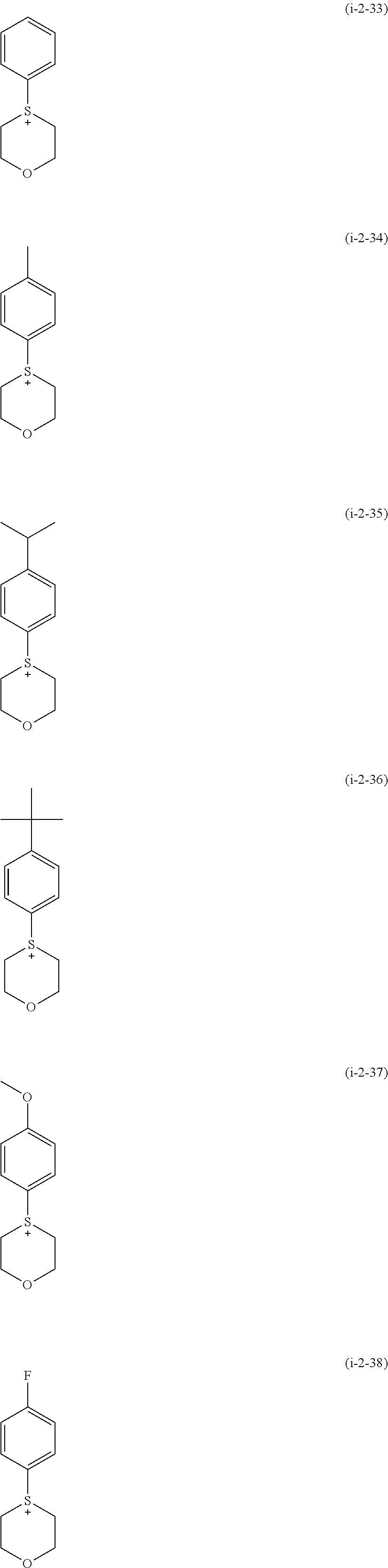

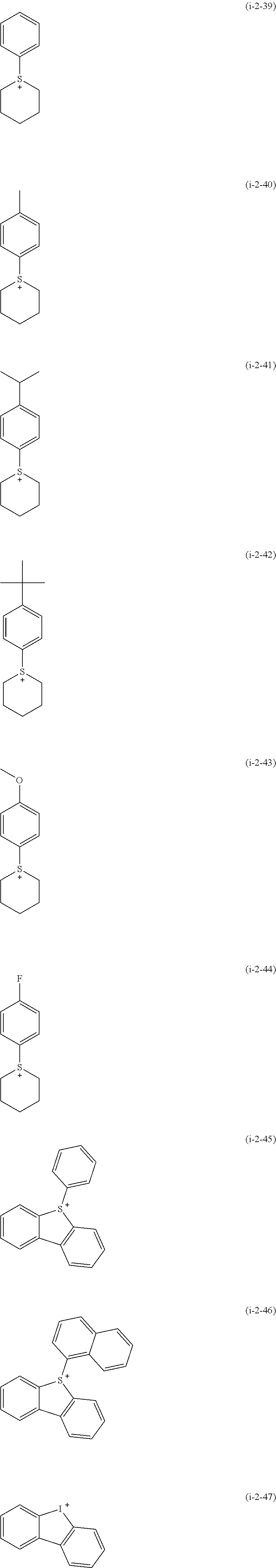

Examples of the repeating unit (1-1) include repeating units represented by the following formulas (1-1-1) to (1-1-22).

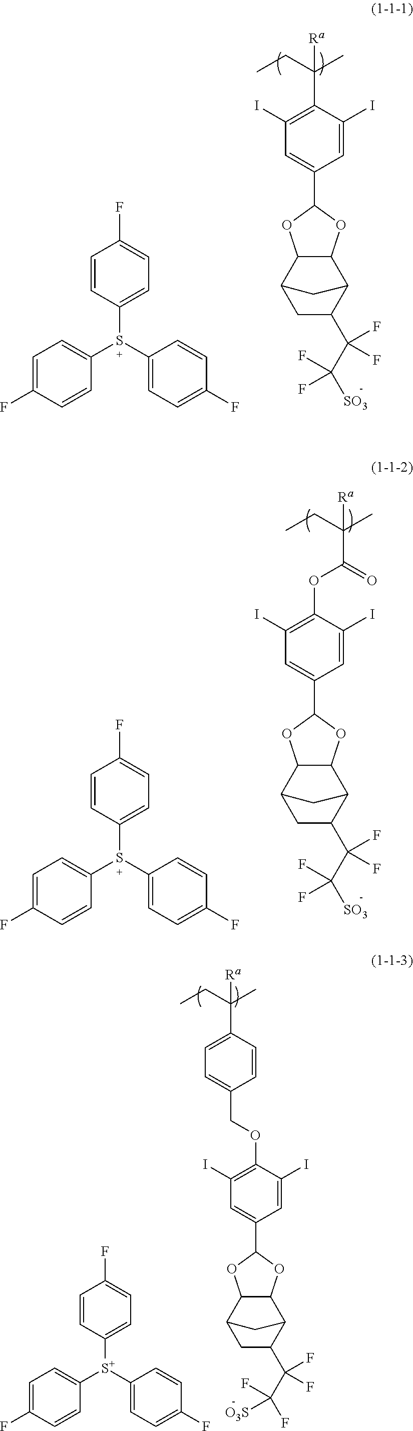

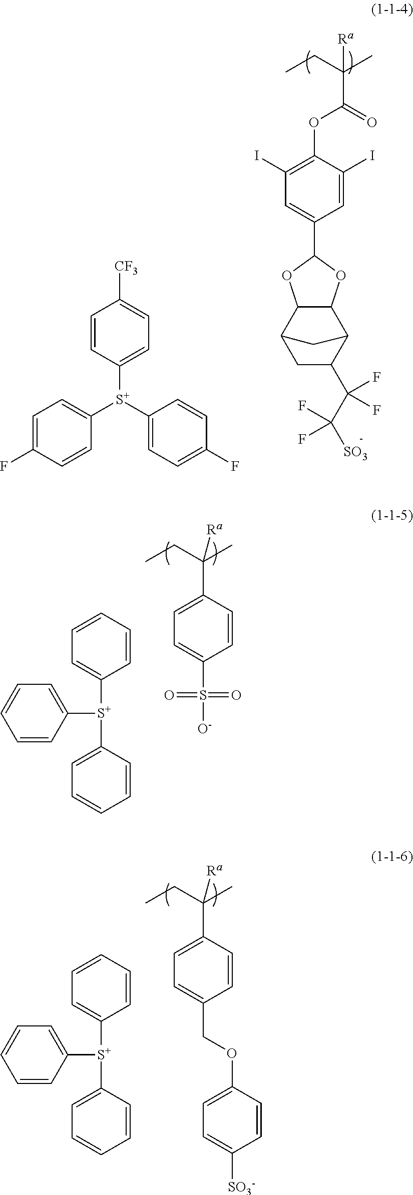

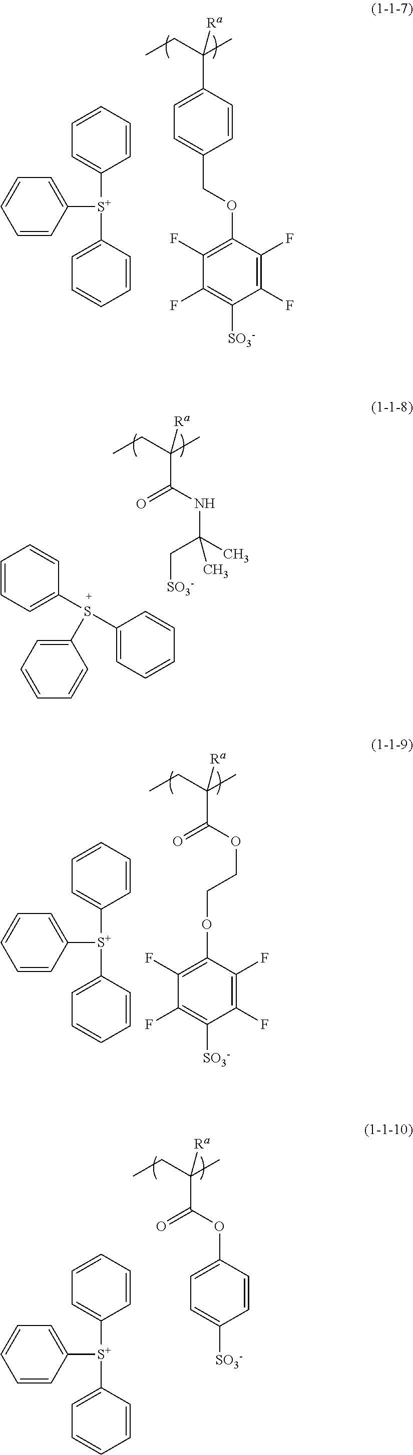

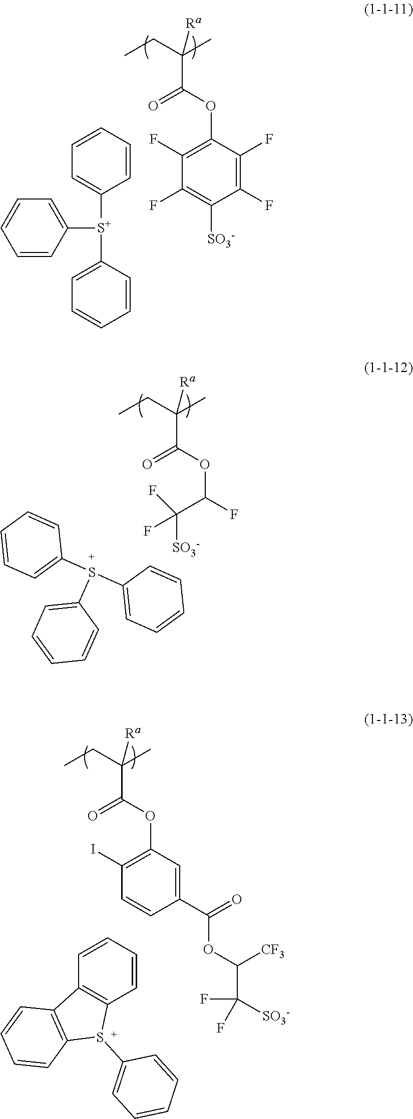

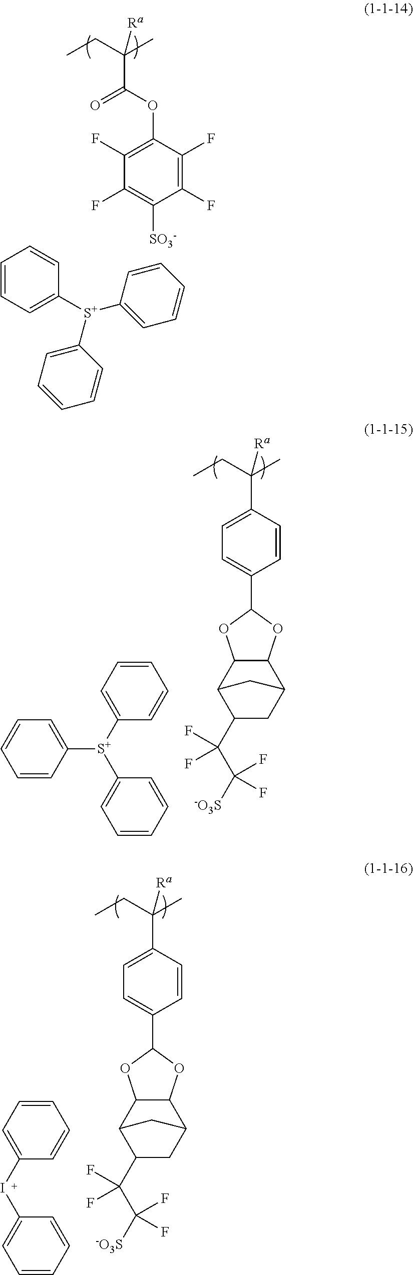

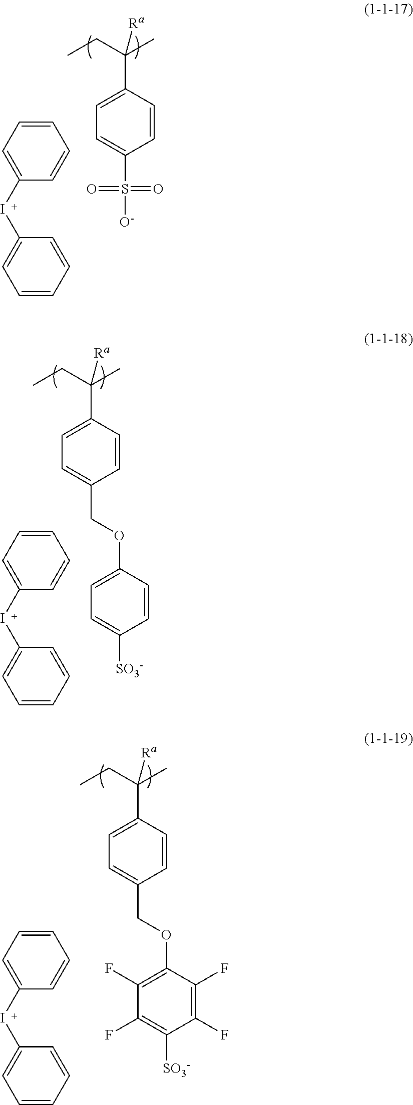

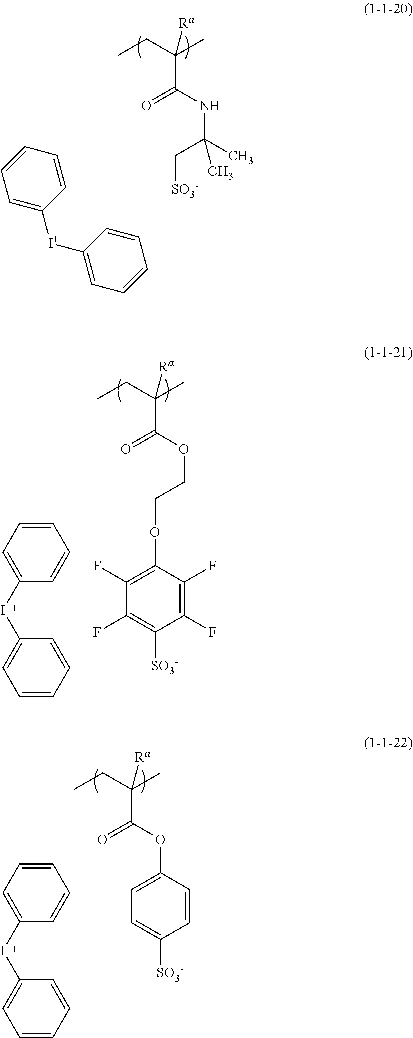

In the formula (1-2), as R^{a} and L², the same groups as R^{a} and L¹ in the formula (1-1) may be employed, respectively.

In the formula (1-2), as the monovalent group having a monovalent onium cation structure represented by Z₂⁺, a group obtained by removing one hydrogen atom from the monovalent onium cation represented by Z₁⁺ in the formula (1-1) can be suitably employed.

The monovalent organic group having 1 to 40 carbon atoms represented by R² is as described above.

Examples of the repeating unit (1-2) include repeating units represented by the following formulas (1-2-1) to (1-2-6).

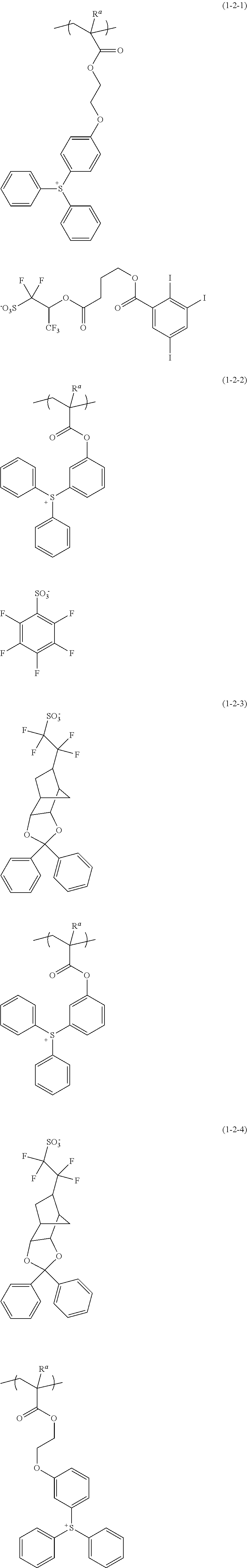

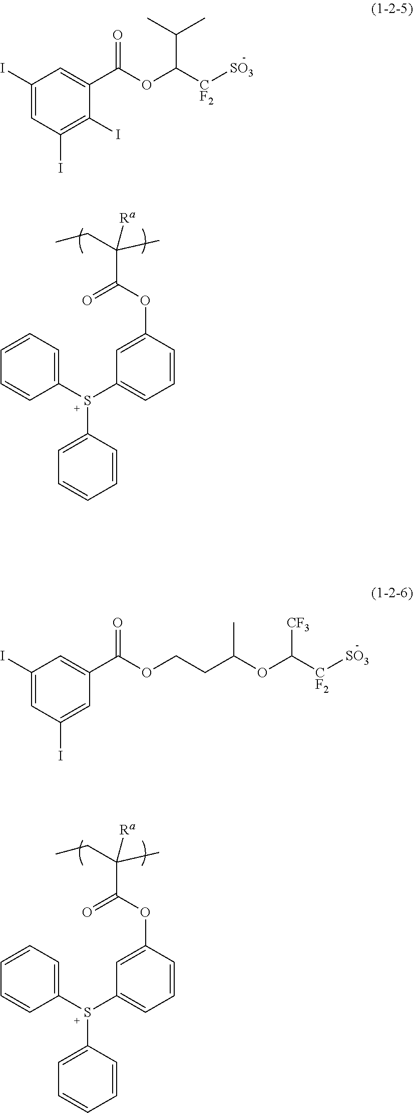

In the formulas, R^{a} has the same definition as that in the formula (1-2).

The lower limit of the content ratio of the repeating unit (1) to all the repeating units constituting the polymer [A] (when there are a plurality of types of the repeating unit (1), the total content ratio is taken) is preferably 1 mol %, more preferably 3 mol %, and still more preferably 5 mol %. The upper limit of the content is preferably 50 mol %, more preferably 20 mol %, and still more preferably 15 mol %. When the content ratio of the repeating unit (1) is set within the above range, pattern rectangularity can be imparted to a resist pattern at a high level.

### (Repeating Unit (2))

The repeating unit (2) is a repeating unit represented by the following formula (2).

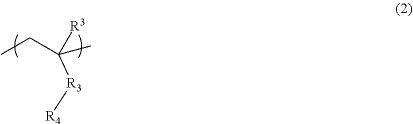

(In the formula (2), R³ is a hydrogen atom or a substituted or unsubstituted monovalent hydrocarbon group having 1 to 20 carbon atoms. L³ is a single bond or a divalent linking group. R⁴ is a group selected from the group consisting of groups represented by any of formulas (2-1) to (2-8).)

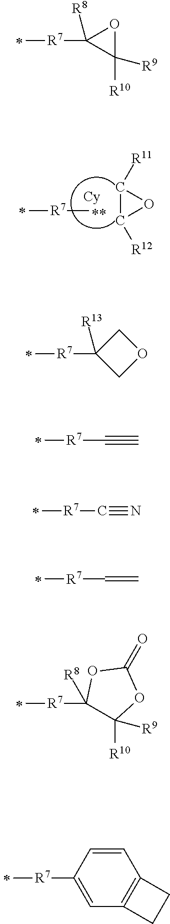

(In the formulas (2-1) to (2-3) and (2-7), R⁸, R⁹, R¹⁰, R¹², and R¹³ are each independently a hydrogen atom or a monovalent organic group having 1 to 20 carbon atoms. In the formula (2-2), Cy is a ring structure having 3 to 20 ring members constituted together with two carbon atoms in the formula. R¹¹ is a hydrogen atom, a monovalent organic group having 1 to 20 carbon atoms, or a single bond. ** is a bond to an atom constituting Cy. It is noted that when R¹¹ is a single bond, R¹¹ is bonded to **. In the formulas (2-1) to (2-8), R⁷ is a divalent organic group having 1 to 20 carbon atoms or a single bond. * is a bond to an atom constituting L³.)

As the monovalent hydrocarbon group having 1 to 20 carbon atoms represented by R³, the groups disclosed as the monovalent hydrocarbon group having 1 to 20 carbon atoms represented by R^{a} in the above formula (1-1) and the like can be suitably employed. When the R³ has a substituent, examples of the substituent include the groups disclosed as the substituent of R^{a} in the formula (1-1).

Examples of the divalent linking group represented by L³ include groups disclosed as the divalent linking group represented by L¹ in the formula (1-1). L³ is preferably a single bond, —COO—* (* is a bond to R⁴), or a benzenediyl group.

In the formulas (2-1) to (2-3) and (2-7), as the monovalent organic group having 1 to 20 carbon atoms represented by R⁸, R⁹, R¹⁰, R¹¹, R¹² and R¹³ (hereinafter also referred to as “R⁸ to R¹³”), groups corresponding to 1 to 20 carbon atoms among the monovalent organic groups having 1 to 40 carbon atoms represented by R² of the formula (1-2) can be suitably employed.

R⁸ to R¹³ are each independently preferably a hydrogen atom or a methyl group, and more preferably, all of them are hydrogen atoms.

In the formula (2-2), as the ring structure having 3 to 20 ring members, which is represented by Cy, formed together with two carbon atoms in the formula, a ring structure corresponding to a monovalent alicyclic hydrocarbon group having 3 to 20 carbon atoms as R^{a} of the formulas (1-1) and (1-2) can be suitably employed. As Cy, cycloalkane rings having 5 to 10 carbon atoms are preferable, and a cyclopentane ring, a cyclohexane ring, and a cycloheptane ring are more preferable.

In the formulas (2-1) to (2-8), as the divalent organic group having 1 to 20 carbon atoms represented by R⁷, a group obtained by removing one hydrogen atom from the monovalent organic group having 1 to 20 carbon atoms represented by R⁸ to R¹³ can be suitably employed.

R⁷ is preferably a single bond, a divalent hydrocarbon group having 1 to 10 carbon atoms, or a combination of a divalent hydrocarbon group having 1 to 10 carbon atoms and a divalent heteroatom-containing linking group. As the divalent hydrocarbon group having 1 to 10 carbon atoms, a methylene group and an ethanediyl group are preferable. The divalent heteroatom-containing linking group is preferably —O—, —CO—, or a combination thereof.

Examples of the repeating unit (2) include repeating units represented by the following formulas (2-1) to (2-16).

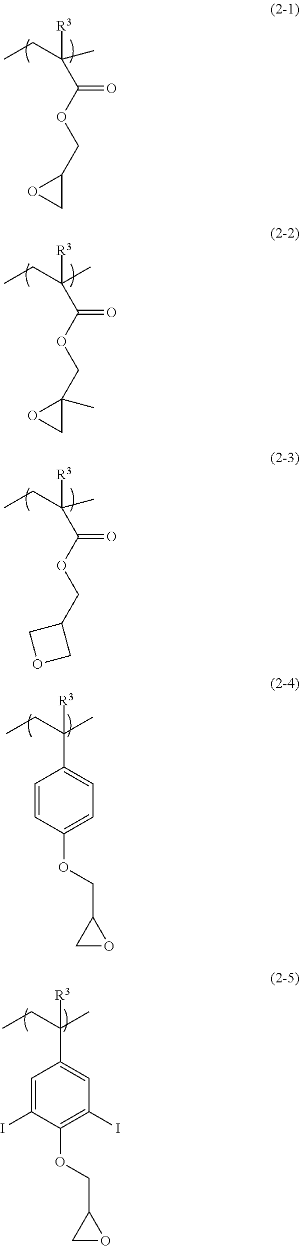

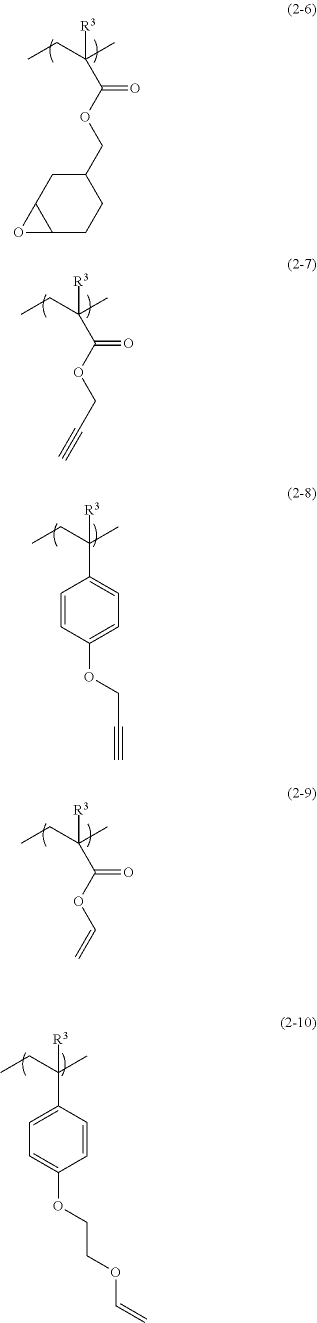

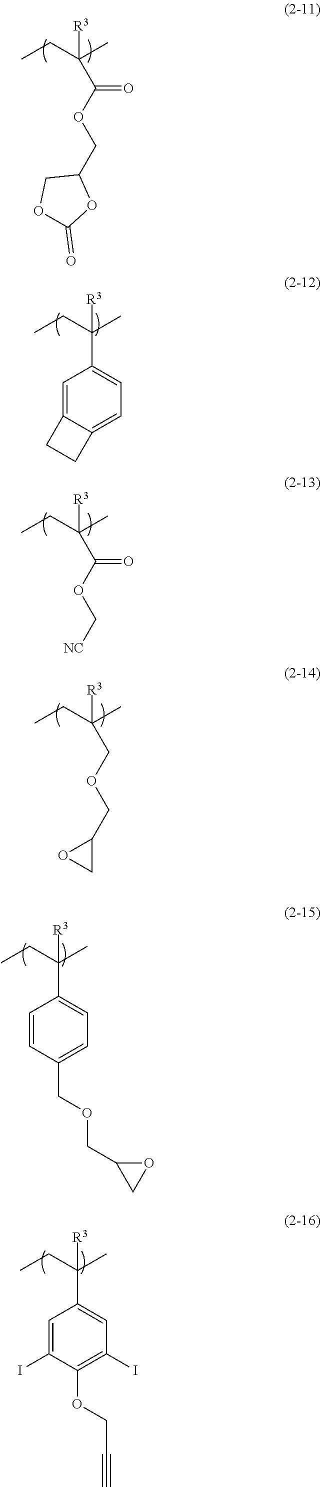

In the formulas (2-1) to (2-16), R³ has the same definition as that in the formula (2).

The lower limit of the content ratio of the repeating unit (2) (when a plurality of types of the repeating unit (2) is contained, the total content ratio is taken) to all the repeating units constituting the polymer [A] is preferably 1 mol %, more preferably 15 mol %, still more preferably 30 mol %, and particularly preferably 40 mol %. The upper limit of the content ratio is preferably 80 mol %, more preferably 70 mol %, still more preferably 60 mol %, and particularly preferably 55 mol %. When the content ratio of the repeating unit (3) is set within the above range, solvent resistance and resist pattern rectangularity can be exhibited at a high level.

### (Repeating Unit (3))

The repeating unit (3) is a repeating unit represented by the following formula (3).

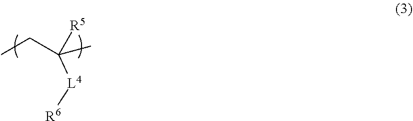

(In the formula (3), R⁵ is a hydrogen atom or a substituted or unsubstituted monovalent hydrocarbon group having 1 to 20 carbon atoms. L⁴ is a single bond or a divalent linking group. R⁶ is a group containing a partial structure represented by the following formula (3-1) or (3-2) (hereinafter each also referred to as “partial structure (3-1)” or the like).)

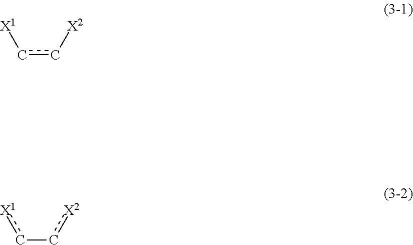

(In the formulas (3-1) and (3-2), X¹ and X² are each independently an oxygen atom, a sulfur atom, or a nitrogen atom. The following formula that is present between C and C in the formula (3-1), that is present between X¹ in the formula (3-2) and C on a left side in the formula, and that is present between X² in the formula (3-2) and C on a right side in the formula each independently represent a single bond or a double bond.

[symbol]

It is noted that a case of corresponding to the formula (3-1) in the formula (3-2) is excluded.)

As the monovalent hydrocarbon group having 1 to 20 carbon atoms represented by R⁵, the groups disclosed as the monovalent hydrocarbon group having 1 to 20 carbon atoms represented by R^{a} in the above formula (1-1) and the like can be suitably employed. When the R³ has a substituent, examples of the substituent include the groups disclosed as the substituent of R^{a} in the formula (1-1).

Examples of the divalent linking group represented by L⁴ include groups disclosed as the divalent linking group represented by L¹ in the formula (1-1). L⁴ is preferably a single bond, —COO—* (* is a bond to R⁴), or a benzenediyl group.

The partial structure (3-1) and the partial structure (3-2) represent only partial structures composed of X¹, X² and two carbon atoms of the formulas (3-1) and (3-2). Accordingly, X¹, X² and two carbon atoms are each bonded to one or more other atoms according to the valence of each atom.

The partial structure (3-1) and the partial structure (3-2) each may constitute either a part of a chain structure or a part of a cyclic structure. When the partial structure (3-1) or the partial structure (3-2) forms a part of a cyclic structure, a carbon-X¹ bond may form a part of one cyclic structure, and a carbon-X² bond may form a part of another cyclic structure.

Where the following formula between carbon and carbon, carbon and X¹, or carbon and X² in the formulas (3-1) and (3-2) represents a double bond, this double bond includes a conjugated system existing when the cyclic structure exhibits aromaticity.

[symbol]

Examples of the partial structure (3-1) and the partial structure (3-2) include structures represented by the following formulas (3-1-1) to (3-1-5) or (3-2-1).

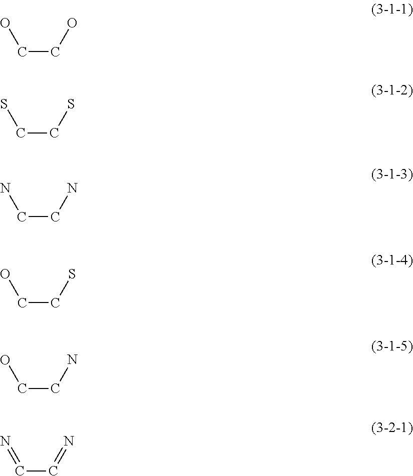

The partial structures are preferably represented by the formulas (3-1-1), (3-1-2), (3-1-3) or (3-2-1).

In the partial structure (3-1), X¹ and X² are each independently preferably included as a part of a hydroxy group, a thiol group, an amino group, or a group obtained by protecting these groups with a protective group. The protective group is preferably a protective group that is deprotected by heating (for example, at 200° C.) or a group that can form a protective structure which is deprotected by heating.

Examples of the protective group or protective structure of a hydroxy group include an acetal structure (examples of the protective group include alkoxymethyl groups), a cyclic acetal structure (a protective structure in the case where both X¹ and X² form a hydroxy group), a carbonate structure (examples of the protective group include alkoxycarbonyl groups), an ester structure (examples of the protective group include an acyl group), a trialkylsilyl group, and a benzyl group.

Examples of the protective group or protective structure of a thiol group include a thioacetal structure (examples of the protective group include alkylthiomethyl groups) and a cyclic thioacetal structure (a protective structure in the case where X¹ and X² form a thiol group).

Examples of the protective group or protective structure of an amino group include a carbamic acid ester structure (examples of the protective group include alkoxycarbonyl groups) and an amide structure (examples of the protective group include an acyl group).

As a structure other than the partial structure (3-1) and the partial structure (3-2) in R⁶, divalent organic groups having 1 to 20 carbon atoms represented by R⁷ in the formulas (2-1) to (2-8) can be suitably employed. In particular, a hydrocarbon group having 1 to 10 carbon atoms and a combined group of a hydrocarbon group having 1 to 10 carbon atoms with —O— are preferable, a chain hydrocarbon group having 1 to 5 carbon atoms and a combined group of a chain hydrocarbon group having 1 to 5 carbon atoms with —O— are more preferable, and a methylene group, an ethanediyl group, a combined group of a methylene group with —O—, and a combined group of an ethanediyl group with —O— are still more preferable.

Examples of the repeating unit (3) include repeating units represented by the following formulas (3-1) to (3-24)

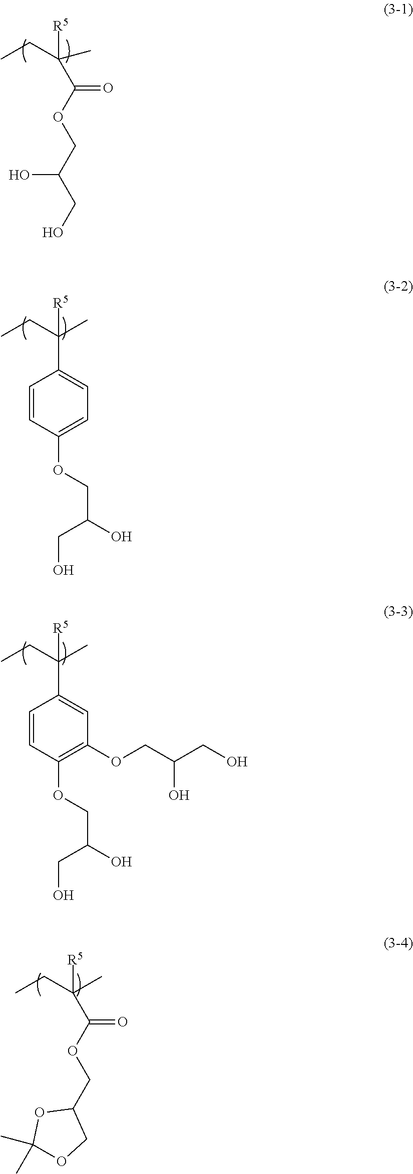

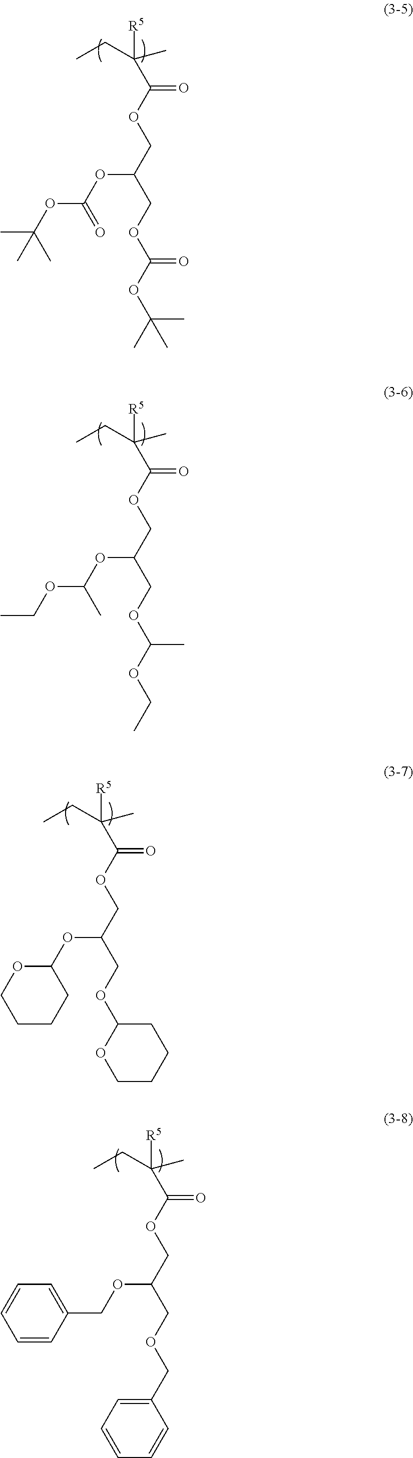

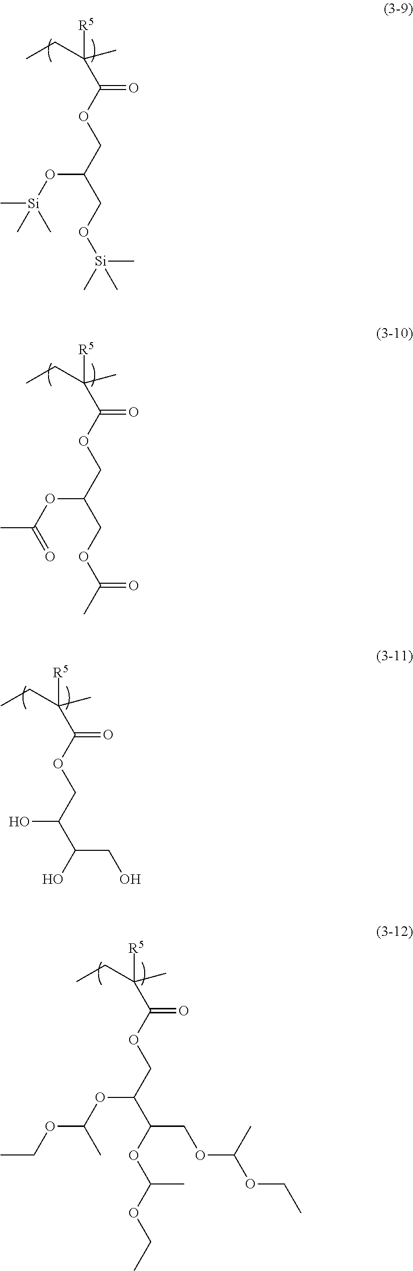

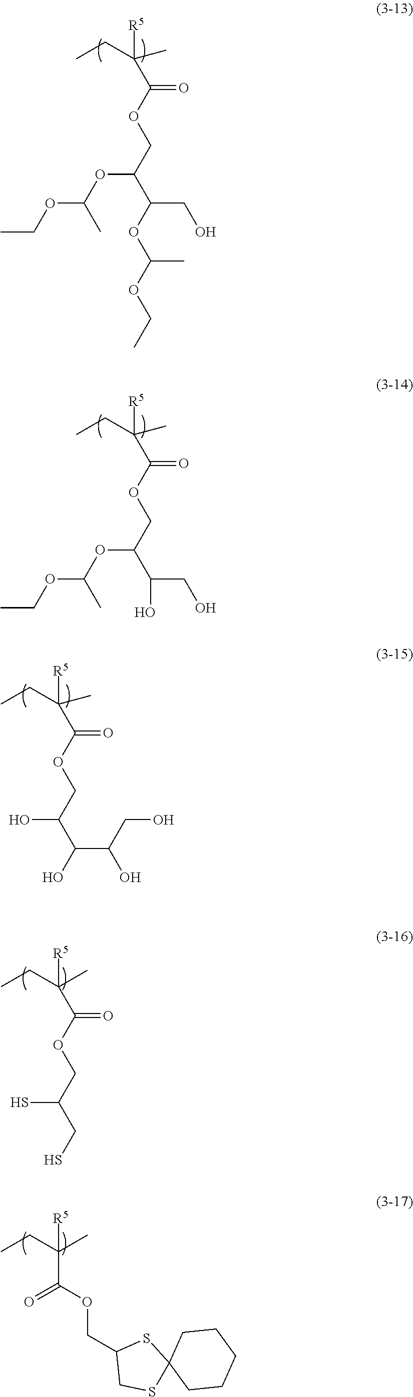

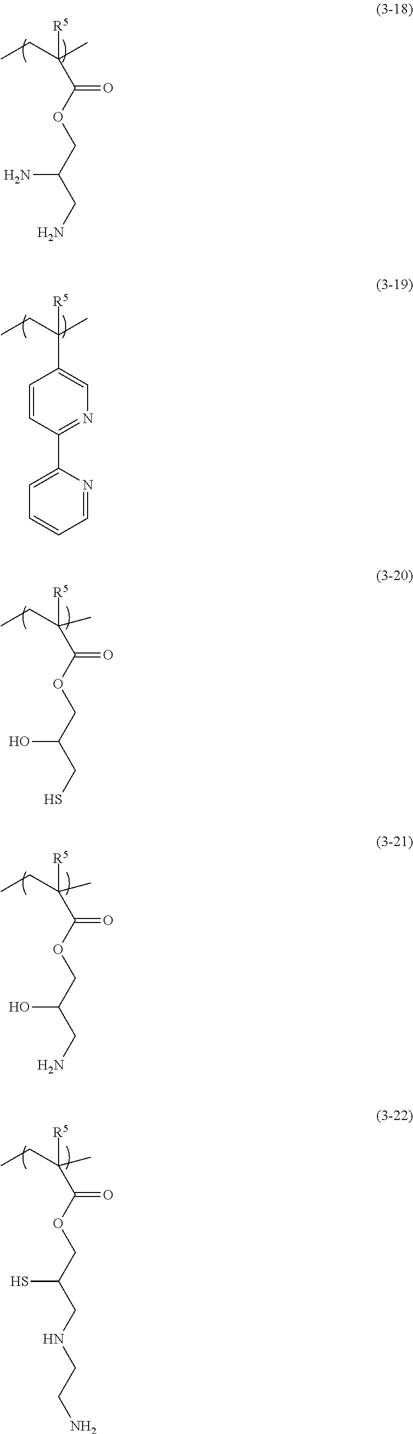

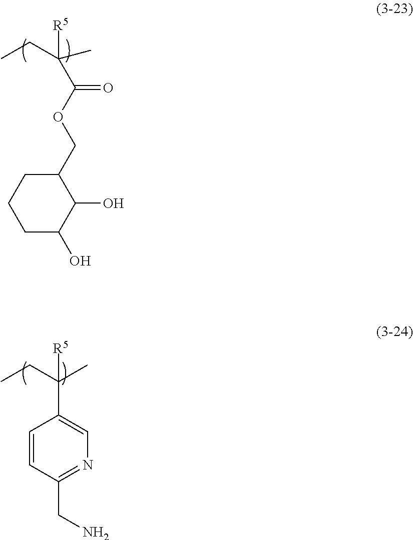

In the formulas (3-1) to (3-24), R⁵ has the same definition as that in the formula (2).

The lower limit of the content ratio of the repeating unit (3) (when a plurality of types of the repeating unit (3) is contained, the total content ratio is taken) to all the repeating units constituting the polymer [A] is preferably 1 mol %, more preferably 20 mol %, and still more preferably 30 mol %. The upper limit of the content ratio is preferably 80 mol %, more preferably 70 mol %, and still more preferably 50 mol %. When the content ratio of the repeating unit (3) is set within the above range, solvent resistance and resist pattern rectangularity can be exhibited at a high level.

The lower limit of the weight average molecular weight (Mw) of the polymer [A] is preferably 2000, more preferably 3000, still more preferably 4000, and particularly preferably 5000. The upper limit of the molecular weight is preferably 20000, more preferably 15000, still more preferably 12000, and particularly preferably 10000. The weight average molecular weight is measured as described in EXAMPLES.

The polydispersity (Mw/Mn) of the polymer [A] is preferably 1 or more and 5 or less, more preferably 1 or more and 3 or less, and still more preferably 1 or more and 2 or less.

The lower limit of the content ratio of the polymer [A] in the composition for forming a resist underlayer film is preferably 0.01% by mass, more preferably 0.05% by mass, still more preferably 0.10% by mass, and particularly preferably 0.12% by mass in the total mass of the polymer [A] and the solvent [C]. The upper limit of the content ratio is preferably 3% by mass, more preferably 2% by mass, still more preferably 1% by mass, and particularly preferably 0.8% by mass in the total mass of the polymer [A] and the solvent [C].

The lower limit of the content ratio of the polymer [A] to the components other than the solvent [C] in the composition for forming a resist underlayer film is preferably 50% by mass, more preferably 60% by mass, and still more preferably 70% by mass. The upper limit of the content ratio may be 100% by mass, may be 98% by mass, or may be 95% by mass.

### [Method for Synthesizing Polymer [A]]

The polymer [A] can be synthesized by conducting radical polymerization, ion polymerization, or the like. For example, when the polymer [A] is synthesized by radical polymerization, the polymer can be synthesized by polymerizing monomers that will afford respective repeating units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### <Solvent [C]>

The solvent [C] is not particularly limited as long as it can dissolve or disperse the compound [A], and optional components contained as necessary.

Examples of the solvent [C] include a hydrocarbon-based solvent, an ester-based solvent, an alcohol-based solvent, a ketone-based solvent, an ether-based solvent, and a nitrogen-containing solvent. The solvent [C] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as y-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, n-propanol, 4-methyl-2-pentanol, and diacetone alcohol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [C], an alcohol-based solvent, a ketone-based solvent, an ether-based solvent, or an ester-based solvent is preferable, a monoalcohol-based solvent, a cyclic ketone-based solvent, a polyhydric alcohol partial ether-based solvent, a polyhydric alcohol partial ether carboxylate-based solvent, or a lactic acid ester-based solvent is more preferable, and diacetone alcohol, cyclohexanone, propylene glycol monomethyl ether, propylene glycol monomethyl ether acetate, or ethyl lactate is still more preferable.

The lower limit of the content ratio of the solvent [C] in the composition for forming a resist underlayer film is preferably 90% by mass, more preferably 97% by mass, and still more preferably 98% by mass. The upper limit of the content ratio is preferably 99.99% by mass, and more preferably 99.95% by mass.

### [Optional Component]

The composition for forming a resist underlayer film may contain an optional component as long as the effects of the present disclosure are not impaired. Examples of the optional component include a crosslinking agent, an acid diffusion controlling agent, a polymer different from the polymer [A], polysiloxane, polycarbosilane, a surfactant, and an acid generator (as a low-molecular form that does not bond to a polymer). The optional component may be used singly, or two or more kinds thereof may be used in combination. Examples of the polymer different from the polymer [A] include polymers having repeating units represented by the following formulas (F-1) to (F-7). The Mw of the polymer is not particularly limited, and is typically 5,000 to 20,000.

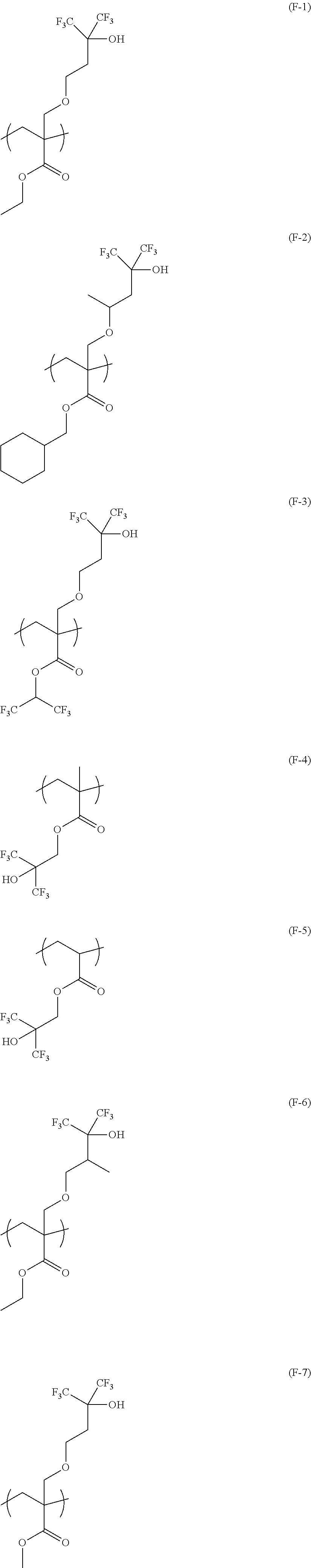

### [Method for Preparing Composition for Forming Resist Underlayer Film]

The composition for forming a resist underlayer film can be prepared by mixing the polymer [A], the solvent [C] and, as necessary, an optional component in a prescribed ratio and preferably filtering the resulting mixture through a membrane filter having a pore size of 0.5 μm or less, or the like.

### [Organic Underlayer Film Forming Step]

In this step, an organic underlayer film is formed directly or indirectly on the substrate before the step of applying a composition for forming a resist underlayer film. This step is an optional step. Through this step, an organic underlayer film is formed directly or indirectly on the substrate.

Examples of the substrate include an insulating film of silicon oxide, silicon nitride, silicon oxynitride, polysiloxane, or the like, and a resin substrate. Furthermore, the substrate may be a substrate on which wiring grooves (trenches), plug grooves (vias), or the like are patterned.

The organic underlayer film can be formed, for example, by applying a composition for forming an organic underlayer film. The method for forming the organic underlayer film by applying a composition for forming an organic underlayer film may be, for example, a method in which a coating film formed by applying the composition for forming an organic underlayer film directly or indirectly to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is formed indirectly on a substrate include a case where an organic underlayer film is formed on a low dielectric insulating film formed on a substrate.

### [Step of Applying Composition for Forming Resist Underlayer Film]

In this step, a composition for forming a resist underlayer film is applied to the organic underlayer film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [C] or the like occurs, so that a resist underlayer film is formed.

When the composition for forming a resist underlayer film is applied directly to the substrate, the organic underlayer film formation step may be omitted.

Next, the coating film formed by the application is heated. The formation of the resist underlayer film is promoted by heating the coating film. More specifically, volatilization or the like of the solvent [C] is promoted by heating the coating film.

The heating of the coating film may be performed either in the air atmosphere or in a nitrogen atmosphere. The lower limit of the heating temperature is preferably 100° C., more preferably 150° C., and still more preferably 200° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 1,200 seconds, and more preferably 600 seconds.

The lower limit of the average thickness of the resist underlayer film to be formed is preferably 0.5 nm, more preferably 1 nm, and still more preferably 2 nm. The upper limit of the average thickness is preferably 15 nm, more preferably 12 nm, still more preferably 8 nm, and particularly preferably 6 nm. The average thickness is measured as described in Examples.

### [Resist Film Forming Step]

In this step, a resist film is formed on the resist underlayer film formed by the step of applying a composition for forming a resist underlayer film. The resist film may be either a coating film or a deposited film, but is preferably a coating film.

Examples of the composition for forming a resist film to be used in this step include a positive or negative chemically amplified resist composition containing a radiation-sensitive acid generating agent, a positive resist composition containing an alkali-soluble resin and a quinonediazide-based photosensitizer, a negative resist composition containing an alkali-soluble resin and a crosslinking agent, and a composition for forming a metal-containing resist film, the composition containing a metal such as tin, zirconium or hafnium.

The resist film preferably contains a metal. Such a metal-containing resist film is preferably formed from a composition for forming a metal-containing resist film.

### (Composition for Forming Metal-Containing Resist Film)

The composition for forming a metal-containing resist film includes a metal-containing compound (hereinafter also referred to as “metal-containing compound (A)”) and a solvent (hereinafter also referred to as “solvent (F)”), and the content ratio of the metal-containing compound (A) to components other than the solvent (F) in the composition for forming a metal-containing resist film is preferably 50% by mass or more. The composition for forming a metal-containing resist film may further contain other components.

### (Metal-Containing Compound (A))

The metal-containing compound (A) is a compound containing a metal atom. The metal-containing compound (A) may be used singly or in combination of two or more kinds thereof. In addition, the metal atom constituting the metal-containing compound (A) may be used singly or in combination of two or more kinds thereof. Here, the “metal atom” is a concept including a metalloid, that is, boron, silicon, germanium, arsenic, antimony, and tellurium.

The metal atom constituting the metal-containing compound (A) is not particularly limited. Examples thereof include metal atoms of Groups 3 to 16. Specific examples of the metal atom include a metal atom of Group 4 such as titanium, zirconium, and hafnium; a metal atom of Group 5 such as tantalum; a metal atom of Group 6 such as chromium and tungsten; a metal atom of Group 8 such as iron and ruthenium; a metal atom of Group 9 such as cobalt; a metal atom of Group 10 such as nickel; a metal atom of Group 11 such as copper; a metal atom of Group 12 such as zinc, cadmium, and mercury; a metal atom of Group 13 such as boron, aluminum, gallium, indium, and thallium; a metal atom of Group 14 such as germanium, tin, and lead; a metal atom of Group 15 such as antimony and bismuth; and a metal atom of Group 16 such as tellurium.

The metal atom constituting the metal-containing compound (A) preferably includes a first metal atom belonging to Group 4, Group 12, or Group 14 and belonging to Period 4, Period 5, or Period 6 in the periodic table. That is, the metal atom preferably contains at least one of titanium, zirconium, hafnium, zinc, cadmium, mercury, germanium, tin, and lead. As described above, the metal-containing compound (A) contains the first metal atom to further promote the release of secondary electrons in the exposed portion of the resist film and the change in solubility of the metal-containing compound (A) in a developer due to the secondary electrons and the like. As a result, the pattern rectangularity can be improved. The first metal atom is preferably tin or zirconium.

The metal-containing compound (A) preferably further has an atom other than the metal atom. Examples of the other atom include a carbon atom, a hydrogen atom, an oxygen atom, a nitrogen atom, a phosphorus atom, a sulfur atom, and a halogen atom. Among these atoms, a carbon atom, a hydrogen atom, and an oxygen atom are preferable. The other atom in the metal-containing compound (A) can be used singly or in combination of two or more kinds thereof.

In the composition for forming a metal-containing resist film, the lower limit of the content of the metal-containing compound (A) in terms of solid content is preferably 70% by mass, more preferably 90% by mass, and still more preferably 95% by mass. The content may be 100% by mass. Here, the solid content in the composition for forming a metal-containing resist film refers to components other than the solvent (F) described later.

### (Synthesis Method of Metal-Containing Compound (A))

The metal-containing compound (A) can be obtained, for example, by a method of performing a hydrolysis condensation reaction, a ligand exchange reaction, or the like on a metal compound having a metal atom and a hydrolyzable group, a hydrolysate of the metal compound, a hydrolysis condensation product of the metal compound, or a combination thereof. The metal compound can be used singly or in combination of two or more kinds thereof.

The metal-containing compound (A) is preferably derived from a metal compound having a metal atom and a hydrolyzable group and represented by formula (4) (hereinafter, also referred to as a “metal compound precursor (1)”). By using such a metal compound precursor (1), a stable metal-containing compound (A) can be obtained.

L^{A}ₐ₁MY_{b1} (4)

In the formula (4), M is a metal atom; L^{A} is a ligand or a monovalent organic group having 1 to 20 carbon atoms; a1 is an integer of 0 to 6; when a1 is 2 or more, the plurality of L¹s may be the same or different from each other; Y is a monovalent hydrolyzable group; b1 is an integer of 2 to 6; the plurality of Ys may be the same or different from each other; and L^{A} is a ligand or an organic group that is not Y.

In this specification, the term “organic group” means a group containing at least one carbon atom, and the term “number of carbon atoms” means the number of carbon atoms constituting the group.

The metal atom represented by M is preferably metal atoms of Group 14, and more preferably tin.

The hydrolyzable group represented by Y can be appropriately changed according to the metal atom represented by M. Examples thereof include a substituted or unsubstituted ethynyl group, a halogen atom, an alkoxy group, an acyloxy group, and a substituted or unsubstituted amino group.

As the substituent in the substituted or unsubstituted ethynyl group and the substituted or unsubstituted amino group represented by Y, a monovalent hydrocarbon group having 1 to 20 carbon atoms is preferable, a chain hydrocarbon group is more preferable, and an alkyl group is still more preferable.

Examples of the halogen atom represented by Y include a fluorine atom, a chlorine atom, a bromine atom, and an iodine atom. Among them, a chlorine atom is preferable.

Examples of the alkoxy group represented by Y include a methoxy group, an ethoxy group, a n-propoxy group, an i-propoxy group, and a n-butoxy group. Among them, an ethoxy group, an i-propoxy group, and a n-butoxy group are preferable.

Examples of the acyloxy group represented by Y include a formyl group, an acetoxy group, an ethyryloxy group, a propionyloxy group, a n-butyryloxy group, a t-butyryloxy group, a t-amyryloxy group, a n-hexanecarbonyloxy group, and a n-octanecarbonyloxy group. Among them, an acetoxy group is preferable.

Examples of the substituted or unsubstituted amino group represented by Y include an amino group, a methylamino group, a dimethylamino group, a diethylamino group, and a dipropylamino group. Among them, a dimethylamino group and a diethylamino group are preferable.

Hereinafter, preferred combinations of the metal atom represented by M and the hydrolyzable group represented by Y will be described. When the metal atom represented by M is tin, the hydrolyzable group represented by Y is preferably a substituted or unsubstituted ethynyl group, a halogen atom, an alkoxy group, an acyloxy group, and a substituted or unsubstituted amino group, and more preferably a halogen atom. When the metal atom represented by M is germanium, the hydrolyzable group represented by Y is preferably a halogen atom, an alkoxy group, an acyloxy group, and a substituted or unsubstituted amino group. When the metal atom represented by M is hafnium, zirconium, and titanium, the hydrolyzable group represented by Y is preferably a halogen atom, an alkoxy group, and an acyloxy group.

Examples of the ligand represented by L^{A} include a monodentate ligand and a multidentate ligand.

Examples of the monodentate ligand include a hydroxo ligand, a nitro ligand, and ammonia.

Examples of the multidentate ligand include a hydroxy acid ester, a β-diketone, a β-ketoester, a malonic acid diester in which a carbon atom at the α-position is optionally substituted, a hydrocarbon having a n bond, a ligand derived from these compounds, and a diphosphine.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

As the monovalent organic group represented by L^{A}, groups corresponding to 1 to 20 carbon atoms among the monovalent organic groups having 1 to 40 carbon atoms represented by R² of the formula (1-2) can be suitably employed.

The lower limit of the carbon number in the monovalent organic group represented by L^{A} is preferably 2, and more preferably 3. On the other hand, the upper limit of the carbon number is preferably 10, and more preferably 5. The monovalent organic group represented by L¹ is preferably a substituted or unsubstituted hydrocarbon group, more preferably a substituted or unsubstituted chain hydrocarbon group or a substituted or unsubstituted aromatic hydrocarbon group, still more preferably a substituted or unsubstituted alkyl group or a substituted or unsubstituted aralkyl group, and particularly preferably an isopropyl group or a benzyl group.

a1 is preferably 1 or 2, and more preferably 1.

b1 is preferably an integer of 2 to 4. By setting b1 to the above numerical value, the content ratio of the metal atom in the metal-containing compound (A) can be increased, and the generation of secondary electrons by the metal-containing compound (A) can be more effectively promoted. As a result, the pattern rectangularity can be improved.

As the metal compound precursor (1), a metal halide compound is preferable, and isopropyltin trichloride or benzyltin trichloride is more preferable.

Examples of the method for performing a hydrolysis condensation reaction on the metal compound precursor (1) include a method in which the metal compound precursor (1) is stirred in water or a solvent containing water in the presence of a base such as tetramethylammonium hydroxide, which is used as necessary. In this case, another compound having a hydrolyzable group may be added, as necessary. The lower limit of the amount of water used in the hydrolysis condensation reaction is preferably 0.2 times mol, more preferably 1 time mol, and still more preferably 3 times mol, in the number of moles, based on the hydrolyzable group of the metal compound precursor (1) and the like. By setting the amount of water in the hydrolysis condensation reaction within the above range, the metal-containing compound (A) can be efficiently obtained.

In the synthesis reaction of the metal-containing compound (A), in addition to the metal compound precursor (1), a compound capable of serving as a multidentate ligand represented by L^{A} in the compound of the formula (4), a compound capable of serving as a bridging ligand, or the like may be added. Examples of the compound capable of serving as a bridging ligand include compounds having two or more groups capable of serving as a ligand, such as a hydroxy group, an isocyanate group, an amino group, an ester group, and an amide group.

In the synthesis reaction of the metal-containing compound (A), the lower limit of the temperature is preferably 0° C., and more preferably 10° C. The upper limit of the temperature is preferably 150° C., more preferably 100° C., and still more preferably 50° C.

In the synthesis reaction of the metal-containing compound (A), the lower limit of the time is preferably 1 minute, more preferably 10 minutes, and still more preferably 1 hour. The upper limit of the time is preferably 100 hours, more preferably 50 hours, still more preferably 24 hours, and particularly preferably 4 hours.

### (Solvent (F))

The solvent (F) is preferably an organic solvent. Specific examples of the organic solvent include organic solvents similar to those exemplified as the solvent [C] in the composition for forming a resist underlayer film described above.

As the solvent (F), an ether-based solvent is preferable, and propylene glycol monoethyl ether is more preferable.

### (Other Optional Components)

The composition for forming a metal-containing resist film may contain other optional components such as a compound capable of serving as a ligand, and a surfactant, in addition to the metal-containing compound (A) and the solvent (F).

### (Compound Capable of Serving as Ligand)

Examples of the compound capable of serving as a ligand include compounds capable of serving as a multidentate ligand or a bridging ligand, and specifically include the same compounds as the compounds capable of serving as a multidentate ligand or a bridging ligand exemplified in the synthesis method of the metal-containing compound (A).

### (Surfactant)

The surfactant is a component that exhibits an action of improving coatability, striation, and the like. Examples of the surfactant include nonionic surfactants, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the product name thereof include KP341 (manufactured by Shin-Etsu Chemical Co., Ltd.), POLYFLOW No. 75, POLYFLOW No. 95 (both manufactured by Kyoeisha Chemical Co., Ltd.), EFTOP EF301, EFTOP EF303, EFTOP EF352 (all manufactured by Tohkem Products Corporation), MEGAFACE F171, MEGAFACE F173 (both manufactured by DIC), Fluorad FC430, Fluorad FC431 (both manufactured by Sumitomo 3M Limited), ASAHIGUARD AG710, SURFLON 5-382, SURFLON SC-101, SURFLON SC-102, SURFLON SC-103, SURFLON SC-104, SURFLON SC-105, SURFLON SC-106 (all manufactured by Asahi Glass Co., Ltd.)

### (Method for Preparation of Composition for Forming Metal-Containing Resist Film)

The composition for forming a metal-containing resist film can be prepared, for example, by mixing the metal-containing compound (A), the solvent (F) and, as necessary, other optional components in a prescribed ratio, and preferably filtering the obtained mixture through a membrane filter having a pore size of 0.4 μm or less. The content ratio of the metal-containing compound (A) to components other than the solvent (F) in the composition for forming a metal-containing resist film is preferably 50% by mass or more. The lower limit of the content ratio of the metal-containing compound (A) is more preferably 60% by mass, and still more preferably 70% by mass. On the other hand, the upper limit of the content ratio is preferably 100% by mass, but may be 98% by mass, or may be 95% by mass.

<Method for Forming Coating Film from Composition for Forming Metal-Containing Resist Film>

The method for applying the composition for forming a metal-containing resist film is not particularly limited, and examples thereof include a spin coating method.

To explain this step in more detail, for example, after applying a composition for forming a metal-containing resist film such that the formed metal-containing resist film has a prescribed thickness, pre-baking (hereinafter also referred to as “PB”) is performed to volatilize the solvent in the coating film to form a resist film.

The PB temperature and the PB time may be appropriately determined according to the type and the like of the composition for forming a metal-containing resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

### [Exposing Step]

In this step, the resist film is exposed to radiation.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and y-rays and corpuscular rays such as electron beam, molecular beams, and ion beams. Among these, electron beam or far-ultraviolet rays are preferable, and electron beam, KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and electron beam or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### [Developing Step]

In this step, at least the exposed resist film is developed. At this time, a part of the resist underlayer film may also be developed. The development may be dissolution in a developer or volatilization by heating or decompression depending on the type and the like of the composition for forming a resist film. Thereby, a resist pattern can be formed.

Examples of the developer in the case of using the developer include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of the organic solvent developer in the case of performing organic solvent development include the same as those disclosed as the examples of the solvent [C] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development. Furthermore, etching using the resist pattern as a mask may be conducted. Examples of a method for etching include dry etching and wet etching.

### <<Composition for Forming a Resist Underlayer Film>>

The composition for forming a resist underlayer film contains the polymer [A], and the solvent [C]. As such a composition for forming a resist underlayer film, the composition for forming a resist underlayer film to be used in the above-described method for manufacturing a semiconductor substrate can be suitably employed.

### EXAMPLES

Hereinafter, Examples are described. The following Examples merely illustrate typical Examples of the present disclosure, and the Examples should not be construed to narrow the scope of the present invention.

### [Weight-Average Molecular Weight (Mw), Number Average Molecular Weight (Mn) and Polydispersity Index (PDI)]

The Mw and Mn of a polymer (x-1) ware measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C. The PDI was calculated from the determined Mw and Mn.

### [Average Thickness of Film]

An average thickness of a film was determined as a value obtained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### <Synthesis of Polymer [A]>

Polymers [A] were each synthesized by the following procedure. The following compounds (a-1) to (a-4), compounds (b-1) to (b-15), and compounds (c-1) to (c-24) as monomers were used for synthesis of the polymers [A].

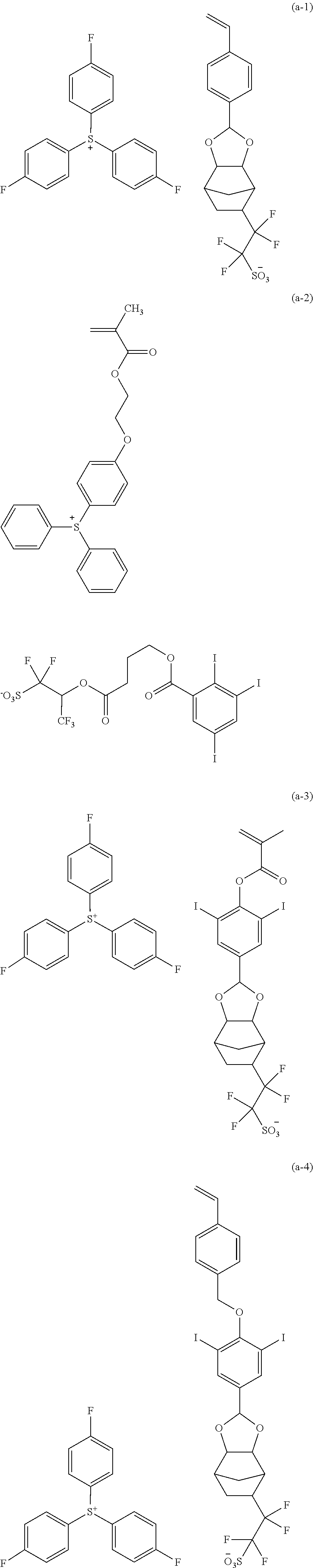

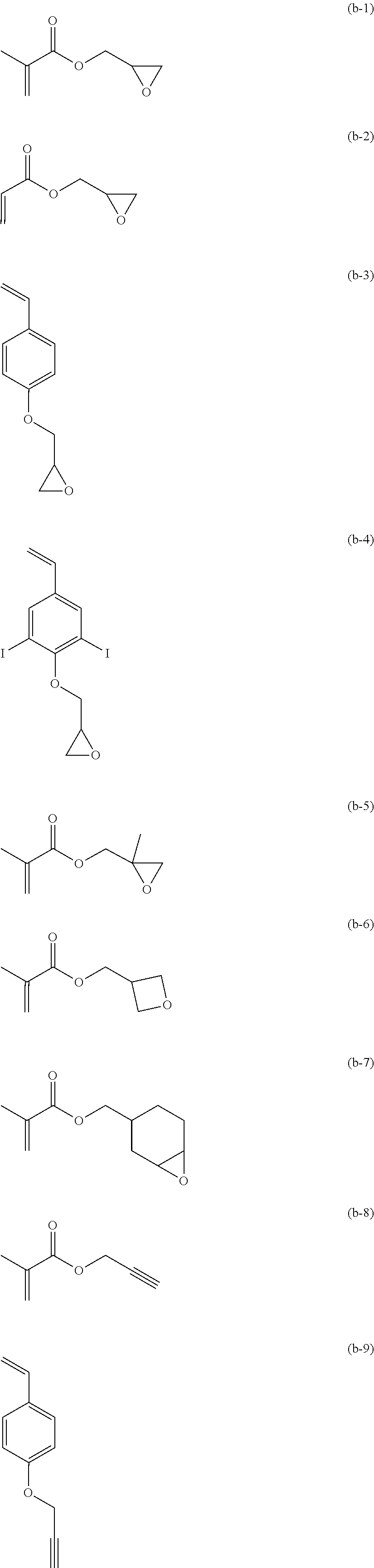

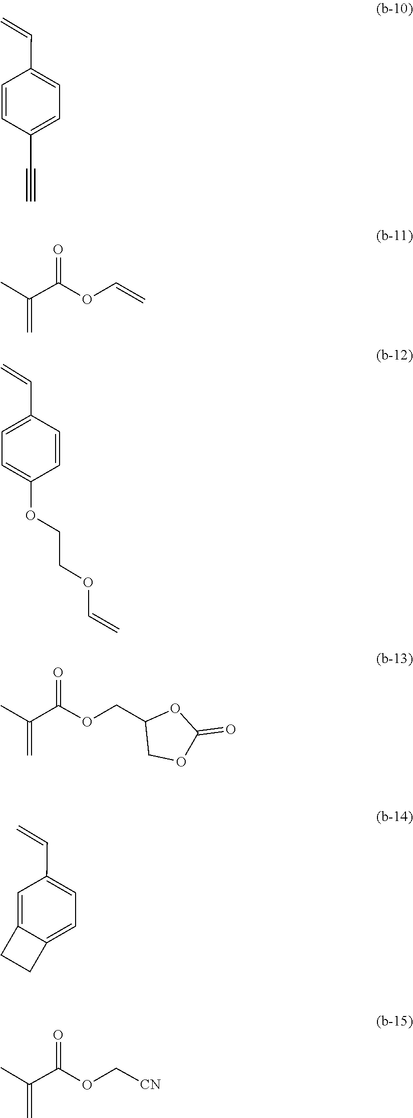

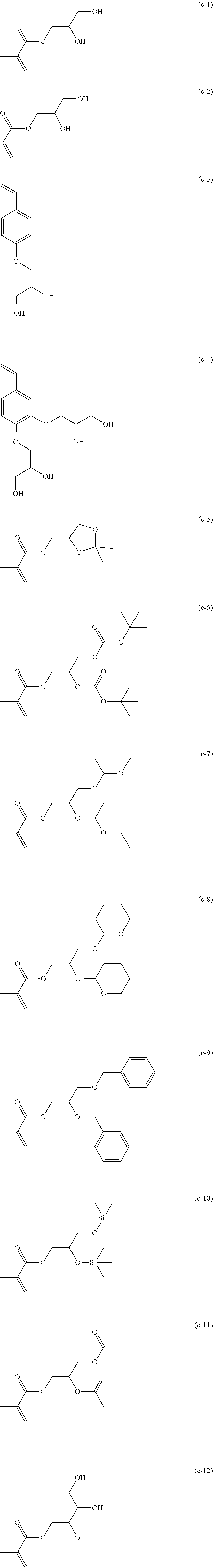

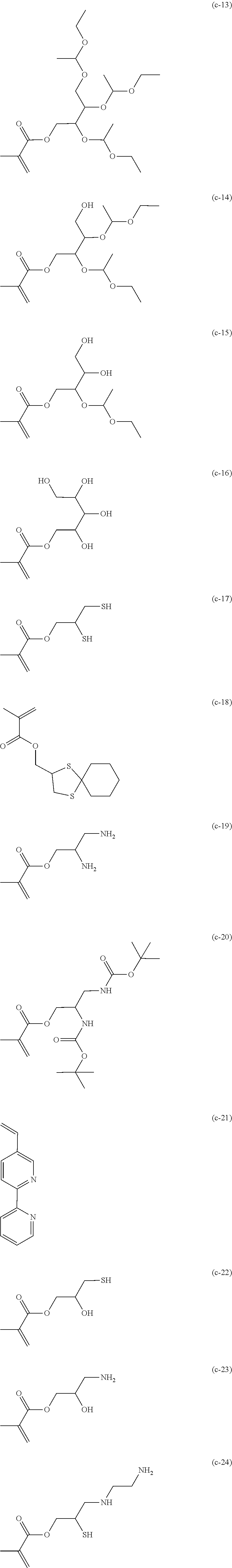

### [Synthesis Example 1-1] (Synthesis of Polymer (A-1))

Into a reaction vessel, 17 g of dimethylacetamide was charged and kept at 80° C., and a mixed liquid of 3.00 g of the compound (a-1), 6.35 g of the compound (b-1), 5.20 g of the compound (c-1), 2.62 g of dimethyl-2,2-azobis(2-methylpropionate), and 34.00 g of dimethylacetamide was added dropwise from a feeder over 3 hours. After the completion of the dropwise addition, the mixture was stirred at 80° C. for 3 hours. The obtained polymerization liquid was precipitated and purified with 10 times amount of methanol, affording 13.6 g of white solid polymer (A-1). The polymer (A-1) had an Mw of 5,500, an Mn of 3,200, and a PDI of 1.7.

### [Synthesis Examples 1-2 to 1-50] (Synthesis of Polymers (A-2) to (A-50))

Polymers (A-2) to (A-50) were obtained as products under the same reaction conditions as in Synthesis Example A-1 except that the monomers and the blending ratios (mol %) shown in the following Table 1 were used. Mw, Mn and PDI of the polymers obtained are shown in Table 1.

TABLE 1

| | | Monomer that affords | | Monomer that affords | | Monomer that affords | | | | |
|---|---|---|---|---|---|---|---|---|---|---|
| | Polymer | repeating unit (1) | | repeating unit (2) | | repeating unit (3) | | | | |
| | [A] | Monomer | mol % | Monomer | mol % | Monomer | mol % | Mw | Mn | PDI |
| Synthesis | A-1 | a-1 | 5 | b-1 | 55 | c-1 | 40 | 5500 | 3200 | 1.7 |
| Example 1-1 | | | | | | | | | | |
| Synthesis | A-2 | a-1 | 10 | b-1 | 50 | c-1 | 40 | 6300 | 3500 | 1.8 |
| Example 1-2 | | | | | | | | | | |
| Synthesis | A-3 | a-1 | 15 | b-1 | 45 | c-1 | 40 | 5800 | 3400 | 1.7 |
| Example 1-3 | | | | | | | | | | |
| Synthesis | A-4 | a-1 | 20 | b-1 | 40 | c-1 | 40 | 6200 | 3400 | 1.8 |
| Example 1-4 | | | | | | | | | | |
| Synthesis | A-5 | a-1 | 50 | b-1 | 30 | c-1 | 20 | 6100 | 3500 | 1.7 |
| Example 1-5 | | | | | | | | | | |
| Synthesis | A-6 | a-1 | 10 | b-1 | 10 | c-1 | 80 | 6600 | 3800 | 1.7 |
| Example 1-6 | | | | | | | | | | |
| Synthesis | A-7 | a-1 | 10 | b-1 | 20 | c-1 | 70 | 5800 | 3400 | 1.7 |
| Example 1-7 | | | | | | | | | | |
| Synthesis | A-8 | a-1 | 10 | b-1 | 40 | c-1 | 50 | 6000 | 3300 | 1.8 |
| Example 1-8 | | | | | | | | | | |
| Synthesis | A-9 | a-1 | 10 | b-1 | 70 | c-1 | 20 | 6800 | 3500 | 1.9 |
| Example 1-9 | | | | | | | | | | |
| Synthesis | A-10 | a-1 | 10 | b-1 | 80 | c-1 | 10 | 6100 | 3300 | 1.8 |
| Example 1-10 | | | | | | | | | | |
| Synthesis | A-11 | a-1 | 10 | b-1 | 50 | c-2 | 40 | 6400 | 3700 | 1.7 |
| Example 1-11 | | | | | | | | | | |
| Synthesis | A-12 | a-1 | 10 | b-1 | 50 | c-3 | 40 | 6600 | 3600 | 1.8 |
| Example 1-12 | | | | | | | | | | |
| Synthesis | A-13 | a-1 | 10 | b-1 | 50 | c-4 | 40 | 5800 | 3400 | 1.7 |
| Example 1-13 | | | | | | | | | | |
| Synthesis | A-14 | a-1 | 10 | b-1 | 50 | c-5 | 40 | 6000 | 3500 | 1.7 |
| Example 1-14 | | | | | | | | | | |
| Synthesis | A-15 | a-1 | 10 | b-1 | 50 | c-6 | 40 | 6800 | 3700 | 1.8 |
| Example 1-15 | | | | | | | | | | |
| Synthesis | A-16 | a-1 | 10 | b-1 | 50 | c-7 | 40 | 6100 | 3200 | 1.9 |
| Example 1-16 | | | | | | | | | | |
| Synthesis | A-17 | a-1 | 10 | b-1 | 50 | c-8 | 40 | 6400 | 3500 | 1.8 |
| Example 1-17 | | | | | | | | | | |
| Synthesis | A-18 | a-1 | 10 | b-1 | 50 | c-9 | 40 | 6600 | 3800 | 1.7 |
| Example 1-18 | | | | | | | | | | |
| Synthesis | A-19 | a-1 | 10 | b-1 | 50 | c-10 | 40 | 7100 | 3900 | 1.8 |
| Example 1-19 | | | | | | | | | | |
| Synthesis | A-20 | a-1 | 10 | b-1 | 50 | c-11 | 40 | 6500 | 3600 | 1.8 |
| Example 1-20 | | | | | | | | | | |
| Synthesis | A-21 | a-1 | 10 | b-1 | 50 | c-12 | 40 | 6600 | 3400 | 1.9 |
| Example 1-21 | | | | | | | | | | |
| Synthesis | A-22 | a-1 | 10 | b-1 | 50 | c-13 | 40 | 6100 | 3300 | 1.8 |
| Example 1-22 | | | | | | | | | | |
| Synthesis | A-23 | a-1 | 10 | b-1 | 50 | c-14 | 40 | 6200 | 3600 | 1.7 |
| Example 1-23 | | | | | | | | | | |
| Synthesis | A-24 | a-1 | 10 | b-1 | 50 | c-15 | 40 | 7200 | 4000 | 1.8 |
| Example 1-24 | | | | | | | | | | |
| Synthesis | A-25 | a-1 | 10 | b-1 | 50 | c-16 | 40 | 5900 | 3200 | 1.8 |
| Example 1-25 | | | | | | | | | | |
| Synthesis | A-26 | a-1 | 10 | b-1 | 50 | c-17 | 40 | 6500 | 3800 | 1.7 |
| Example 1-26 | | | | | | | | | | |
| Synthesis | A-27 | a-1 | 10 | b-1 | 50 | c-18 | 40 | 6600 | 3600 | 1.8 |
| Example 1-27 | | | | | | | | | | |
| Synthesis | A-28 | a-1 | 10 | b-1 | 50 | c-19 | 40 | 6100 | 3200 | 1.9 |
| Example 1-28 | | | | | | | | | | |
| Synthesis | A-29 | a-1 | 10 | b-1 | 50 | c-20 | 40 | 6200 | 3400 | 1.8 |
| Example 1-29 | | | | | | | | | | |
| Synthesis | A-30 | a-1 | 10 | b-1 | 50 | c-21 | 40 | 7200 | 4000 | 1.8 |
| Example 1-30 | | | | | | | | | | |
| Synthesis | A-31 | a-1 | 10 | b-1 | 50 | c-22 | 40 | 5800 | 3200 | 1.8 |
| Example 1-31 | | | | | | | | | | |
| Synthesis | A-32 | a-1 | 10 | b-1 | 50 | c-23 | 40 | 6000 | 3100 | 1.9 |
| Example 1-32 | | | | | | | | | | |
| Synthesis | A-33 | a-1 | 10 | b-1 | 50 | c-24 | 40 | 6800 | 3700 | 1.8 |
| Example 1-33 | | | | | | | | | | |
| Synthesis | A-34 | a-2 | 10 | b-1 | 50 | c-1 | 40 | 6100 | 3300 | 1.8 |
| Example 1-34 | | | | | | | | | | |
| Synthesis | A-35 | a-3 | 10 | b-1 | 50 | c-1 | 40 | 6400 | 3300 | 1.9 |
| Example 1-35 | | | | | | | | | | |
| Synthesis | A-36 | a-4 | 10 | b-1 | 50 | c-1 | 40 | 6600 | 3600 | 1.8 |
| Example 1-36 | | | | | | | | | | |
| Synthesis | A-37 | a-1 | 10 | b-2 | 50 | c-1 | 40 | 7100 | 4100 | 1.7 |
| Example 1-37 | | | | | | | | | | |
| Synthesis | A-38 | a-1 | 10 | b-3 | 50 | c-1 | 40 | 6600 | 3800 | 1.7 |
| Example 1-38 | | | | | | | | | | |
| Synthesis | A-39 | a-1 | 10 | b-4 | 50 | c-1 | 40 | 6100 | 3200 | 1.9 |
| Example 1-39 | | | | | | | | | | |
| Synthesis | A-40 | a-1 | 10 | b-5 | 50 | c-1 | 40 | 6500 | 3400 | 1.9 |
| Example 1-40 | | | | | | | | | | |
| Synthesis | A-41 | a-1 | 10 | b-6 | 50 | c-1 | 40 | 6900 | 3800 | 1.8 |
| Example 1-41 | | | | | | | | | | |
| Synthesis | A-42 | a-1 | 10 | b-7 | 50 | c-1 | 40 | 6200 | 3600 | 1.7 |
| Example 1-42 | | | | | | | | | | |
| Synthesis | A-43 | a-1 | 10 | b-8 | 50 | c-1 | 40 | 6700 | 3900 | 1.7 |
| Example 1-43 | | | | | | | | | | |
| Synthesis | A-44 | a-1 | 10 | b-9 | 50 | c-1 | 40 | 6400 | 3300 | 1.9 |
| Example 1-44 | | | | | | | | | | |
| Synthesis | A-45 | a-1 | 10 | b-10 | 50 | c-1 | 40 | 6600 | 3600 | 1.8 |
| Example 1-45 | | | | | | | | | | |
| Synthesis | A-46 | a-1 | 10 | b-11 | 50 | c-1 | 40 | 7100 | 3900 | 1.8 |
| Example 1-46 | | | | | | | | | | |
| Synthesis | A-47 | a-1 | 10 | b-12 | 50 | c-1 | 40 | 7200 | 4000 | 1.8 |
| Example 1-47 | | | | | | | | | | |
| Synthesis | A-48 | a-1 | 10 | b-13 | 50 | c-1 | 40 | 5800 | 3400 | 1.7 |
| Example 1-48 | | | | | | | | | | |
| Synthesis | A-49 | a-1 | 10 | b-14 | 50 | c-1 | 40 | 6000 | 3500 | 1.7 |
| Example 1-49 | | | | | | | | | | |
| Synthesis | A-50 | a-1 | 10 | b-15 | 50 | c-1 | 40 | 6800 | 3700 | 1.8 |
| Example 1-50 | | | | | | | | | | |

### <Synthesis of Polymer [B]>

A polymer represented by the following formula (B-1) (hereinafter also referred to as “polymer (B-1)”) was synthesized by the following procedure. In the following formula, the number attached to a repeating unit represents the content ratio (mol %) of the repeating unit.

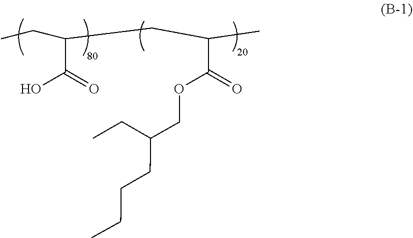

### [Synthesis Example 2-1] (Synthesis of Polymer (B-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-1). The Mw of the polymer (B-1) was 6,500.

### <Preparation of Composition>

The polymers [A], the polymers [B], the solvents [C], and optional components used for the preparation of compositions are shown below.

### [Polymer [A]]

Polymers (A-1) to (A-50) Synthesized Above

### [Polymer [B]]

Polymers (B-1) Synthesized Above

### [Solvent [C]]

C-1: Propylene glycol monomethyl ether acetate
C-2: Propylene glycol monomethyl ether
C-3: Ethyl lactate
C-4: Diacetone alcohol
C-5: Cyclohexanone

### [Optional Components]

D-1: Compound represented by the following formula (D-1)
D-2: Compound represented by the following formula (D-2)
E-1: Compound represented by the following formula (E-1)
F-1: Polymer (Mw: 10,000) having a repeating unit represented by the following formula (F-1)
F-2: Polymer (Mw: 11,000) having a repeating unit represented by the following formula (F-2)
F-3: Polymer (Mw: 11,000) having a repeating unit represented by the following formula (F-3)
F-4: Polymer (Mw: 10,000) having a repeating unit represented by the following formula (F-4)

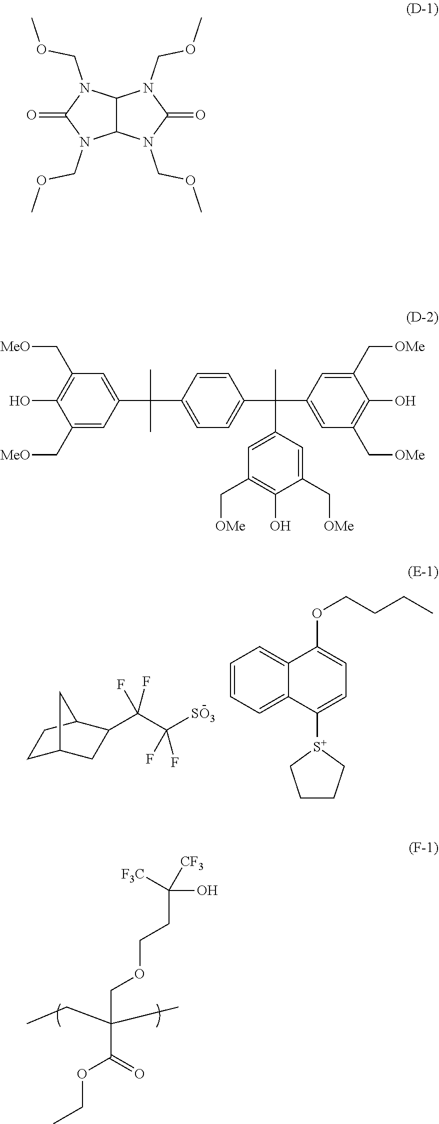

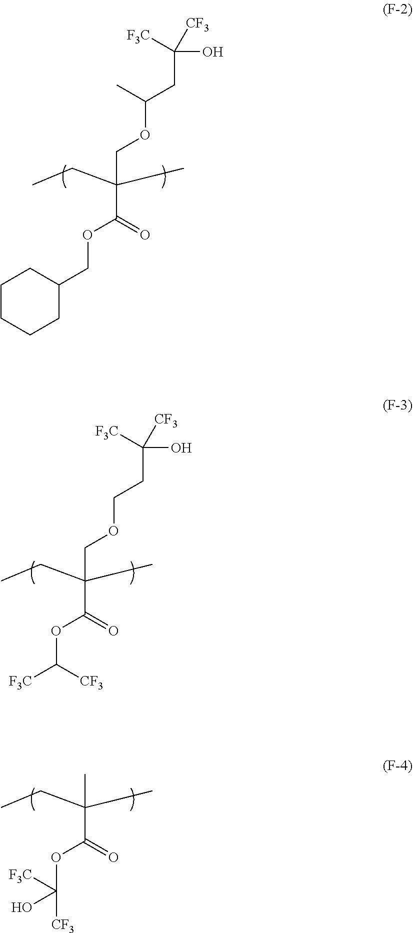

### Example 1

In 80000 parts by mass of (C-1) and 2000 parts by mass of (C-5) as the solvent [C], 50 parts by mass of (A-1) as the polymer [A] was dissolved. The resulting solution was filtered through a polytetrafluoroethylene (PTFE) membrane filter having a pore size of 0.45 μm to prepare composition (J-1).

### Examples 2 to 54 and Comparative Example 1

Compositions (J-2) to (J-54) and (CJ-1) were prepared in the same manner as in Example 1 except that the components of the types and contents shown in the following Table 2 were used. Each “-” in the columns [A], [B], and optional component in Table 1 indicates that the corresponding component was not used.

TABLE 2

| | | Polymer [A] | | Polymer [B] | | Solvent [C] | | Optional component | |
|---|---|---|---|---|---|---|---|---|---|
| | | | Content | | Content | | Content | | Content |
| | | | (parts by | | (parts by | | (parts by | | (parts by |
| | Composition | Type | mass) | Type | mass) | Type | mass) | Type | mass) |
| Example 1 | J-1 | A-1 | 50 | — | — | C-1/C-5 | 8000/2000 | — | — |
| Example 2 | J-2 | A-2 | 50 | — | — | C-1/C-5 | 8000/2000 | — | — |
| Example 3 | J-3 | A-3 | 50 | — | — | C-1/C-5 | 8000/2000 | — | — |
| Example 4 | J-4 | A-4 | 50 | — | — | C-1/C-5 | 8000/2000 | — | — |
| Example 5 | J-5 | A-5 | 50 | — | — | C-1/C-5 | 8000/2000 | — | — |
| Example 6 | J-6 | A-6 | 50 | — | — | C-1/C-5 | 8000/2000 | — | — |
| Example 7 | J-7 | A-7 | 50 | — | — | C-1/C-5 | 8000/2000 | — | — |
| Example 8 | J-8 | A-8 | 50 | — | — | C-1/C-5 | 8000/2000 | — | — |
| Example 9 | J-9 | A-9 | 50 | — | — | C-1/C-5 | 8000/2000 | — | — |
| Example 10 | J-10 | A-10 | 50 | — | — | C-1/C-5 | 8000/2000 | — | — |
| Example 11 | J-11 | A-11 | 50 | — | — | C-1/C-5 | 8000/2000 | — | — |
| Example 12 | J-12 | A-12 | 50 | — | — | C-1/C-5 | 8000/2000 | — | — |
| Example 13 | J-13 | A-13 | 50 | — | — | C-1/C-5 | 8000/2000 | — | — |
| Example 14 | J-14 | 4-14 | 50 | — | — | C-1/C-5 | 8000/2000 | — | — |
| Example 15 | J-15 | A-15 | 50 | — | — | C-1/C-5 | 8000/2000 | — | — |
| Example 16 | J-16 | A-16 | 50 | — | — | C-1/C-5 | 8000/2000 | — | — |
| Example 17 | J-17 | A-17 | 50 | — | — | C-1/C-5 | 8000/2000 | — | — |
| Example 18 | J-18 | A-18 | 50 | — | — | C-1/C-5 | 8000/2000 | — | — |
| Example 19 | J-19 | A-19 | 50 | — | — | C-1/C-5 | 8000/2000 | — | — |
| Example 20 | J-20 | A-20 | 50 | — | — | C-1/C-5 | 8000/2000 | — | — |
| Example 21 | J-21 | A-21 | 50 | — | — | C-1/C-5 | 8000/2000 | — | — |
| Example 22 | J-22 | A-22 | 50 | — | — | C-1/C-5 | 8000/2000 | — | — |
| Example 23 | J-23 | A-23 | 50 | — | — | C-1/C-5 | 8000/2000 | — | — |
| Example 24 | J-24 | A-24 | 50 | — | — | C-1/C-5 | 8000/2000 | — | — |
| Example 25 | J-25 | A-25 | 50 | — | — | C-1/C-5 | 8000/2000 | — | — |
| Example 26 | J-26 | A-26 | 50 | — | — | C-1/C-5 | 8000/2000 | — | — |
| Example 27 | J-27 | A-27 | 50 | — | — | C-1/C-5 | 8000/2000 | — | — |
| Example 28 | J-28 | A-28 | 50 | — | — | C-1/C-5 | 8000/2000 | — | — |
| Example 29 | J-29 | A-29 | 50 | — | — | C-1/C-5 | 8000/2000 | — | — |
| Example 30 | J-30 | A-30 | 50 | — | — | C-1/C-5 | 8000/2000 | — | — |
| Example 31 | J-31 | A-31 | 50 | — | — | C-1/C-5 | 8000/2000 | — | — |
| Example 32 | J-32 | A-32 | 50 | — | — | C-1/C-5 | 8000/2000 | — | — |
| Example 33 | J-33 | A-33 | 50 | — | — | C-1/C-5 | 8000/2000 | — | — |
| Example 34 | J-34 | A-34 | 50 | — | — | C-1/C-5 | 8000/2000 | — | — |
| Example 35 | J-35 | A-35 | 50 | — | — | C-1/C-5 | 8000/2000 | — | — |
| Example 36 | J-36 | A-36 | 50 | — | — | C-1/C-5 | 8000/2000 | — | — |
| Example 37 | J-37 | A-37 | 50 | — | — | C-1/C-5 | 8000/2000 | — | — |
| Example 38 | J-38 | A-38 | 50 | — | — | C-1/C-5 | 8000/2000 | — | — |
| Example 39 | J-39 | A-39 | 50 | — | — | C-1/C-5 | 8000/2000 | — | — |
| Example 40 | J-40 | A-40 | 50 | — | — | C-1/C-5 | 8000/2000 | — | — |
| Example 41 | J-41 | A-41 | 50 | — | — | C-1/C-5 | 8000/2000 | — | — |
| Example 42 | J-42 | A-42 | 50 | — | — | C-1/C-5 | 8000/2000 | — | — |
| Example 43 | J-43 | A-43 | 50 | — | — | C-1/C-5 | 8000/2000 | — | — |
| Example 44 | J-44 | A-44 | 50 | — | — | C-1/C-5 | 8000/2000 | — | — |
| Example 45 | J-45 | A-45 | 50 | — | — | C-1/C-5 | 8000/2000 | — | — |
| Example 46 | J-46 | A-46 | 50 | — | — | C-1/C-5 | 8000/2000 | — | — |
| Example 47 | J-47 | A-47 | 50 | — | — | C-1/C-5 | 8000/2000 | — | — |
| Example 48 | J-48 | A-48 | 50 | — | — | C-1/C-5 | 8000/2000 | — | — |
| Example 49 | J-49 | A-49 | 50 | — | — | C-1/C-5 | 8000/2000 | — | — |
| Example 50 | J-50 | A-50 | 50 | — | — | C-1/C-5 | 8000/2000 | — | — |
| Example 51 | J-51 | A-8 | 50 | — | — | C-1/C-5 | 8000/2000 | D-2/F-1 | 3/5 |
| Example 52 | J-52 | A-8 | 50 | — | — | C-1/C-5 | 8000/2000 | F-2 | 5 |
| Example 53 | J-53 | A-8 | 50 | — | — | C-1/C-5 | 8000/2000 | F-3 | 5 |
| Example 54 | J-54 | A-8 | 50 | — | — | C-1/C-5 | 8000/2000 | F-4 | 5 |
| Comparative | CJ-1 | — | — | B-1 | 67 | C-1/C-5 | 8000/2000 | D-1/E-1 | 33/5 |
| Example 1 | | | | | | | | | |

### <Evaluation>

Using the compositions for forming a resist underlayer film prepared as described above, the rectangularity of a resist pattern was evaluated by the following method. The evaluation results are shown in the following Table 3.

### <Preparation of Resist Composition (R-1)>

Resist composition (R-1) was prepared by mixing 100 parts by mass of resin (r-1), 20 parts by mass of an acid generator (H-1), 50 mol % of an acid diffusion controlling agent (G-1) with respect to the acid generator (H-1), and 7700 parts by mass of propylene glycol monomethyl ether acetate and 3300 parts by mass of propylene glycol monomethyl ether as solvents, and filtering the mixture through a membrane filter having a pore size of 0.2 μm.

The resin (r-1) was a polymer in which the content ratios of repeating units derived from the following monomer (M-1) and monomer (M-2) were 50 mol % and 50 mol %, respectively, and had an Mw of 6,400 and an Mw/Mn of 1.50. As the acid generator (H-1) and the acid diffusion controlling agent (G-1), the following compounds were used.

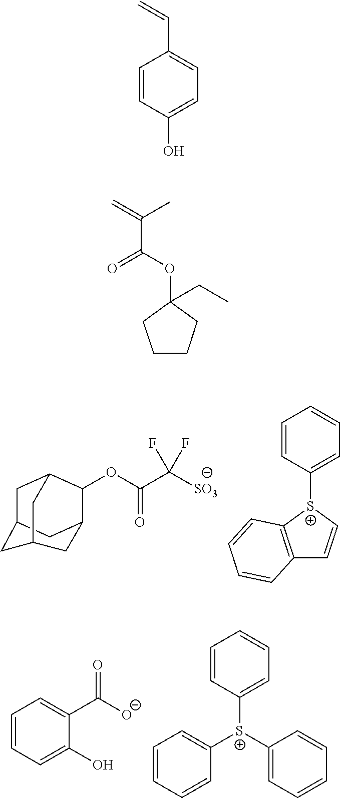

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. To the silicon-containing film formed as described above was applied the composition for forming a resist underlayer film prepared above, heated at 250° C. for 60 sec, and then cooled at 23° C. for 30 sec. Thus, a resist underlayer film having an average thickness of 5 nm was formed. To the resist underlayer film formed as described above was applied a resist composition (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 26 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation on which a resist pattern having 1:1 line and space with line width of 26 nm was formed. A scanning electron microscope (“SU8220” available from Hitachi High-Technologies Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 3

| | | | Resist pattern |
|---|---|---|---|
| | Composition | Resist composition | rectangularity |
| Example 1 | J-1 | R-1 | A |
| Example 2 | J-2 | R-1 | A |
| Example 3 | J-3 | R-1 | A |
| Example 4 | J-4 | R-1 | A |
| Example 5 | J-5 | R-1 | B |
| Example 6 | J-6 | R-1 | B |
| Example 7 | J-7 | R-1 | A |
| Example 8 | J-8 | R-1 | A |
| Example 9 | J-9 | R-1 | A |
| Example 10 | J-10 | R-1 | B |
| Example 11 | J-11 | R-1 | A |
| Example 12 | J-12 | R-1 | A |
| Example 13 | J-13 | R-1 | A |
| Example 14 | J-14 | R-1 | A |
| Example 15 | J-15 | R-1 | A |
| Example 16 | J-16 | R-1 | A |
| Example 17 | J-17 | R-1 | A |
| Example 18 | J-18 | R-1 | A |
| Example 19 | J-19 | R-1 | A |
| Example 20 | J-20 | R-1 | A |
| Example 21 | J-21 | R-1 | A |
| Example 22 | J-22 | R-1 | A |
| Example 23 | J-23 | R-1 | A |
| Example 24 | J-24 | R-1 | A |
| Example 25 | J-25 | R-1 | A |
| Example 26 | J-26 | R-1 | A |
| Example 27 | J-27 | R-1 | A |
| Example 28 | J-28 | R-1 | A |
| Example 29 | J-29 | R-1 | A |
| Example 30 | J-30 | R-1 | A |
| Example 31 | J-31 | R-1 | A |
| Example 32 | J-32 | R-1 | A |
| Example 33 | J-33 | R-1 | A |
| Example 34 | J-34 | R-1 | A |
| Example 35 | J-35 | R-1 | A |
| Example 36 | J-36 | R-1 | A |
| Example 37 | J-37 | R-1 | A |
| Example 38 | J-38 | R-1 | A |
| Example 39 | J-39 | R-1 | A |
| Example 40 | J-40 | R-1 | A |
| Example 41 | J-41 | R-1 | A |
| Example 42 | J-42 | R-1 | A |
| Example 43 | J-43 | R-1 | A |
| Example 44 | J-44 | R-1 | A |
| Example 45 | J-45 | R-1 | A |
| Example 46 | J-46 | R-1 | A |
| Example 47 | J-47 | R-1 | A |
| Example 48 | J-48 | R-1 | A |
| Example 49 | J-49 | R-1 | A |
| Example 50 | J-50 | R-1 | A |
| Example 51 | J-51 | R-1 | A |
| Example 52 | J-52 | R-1 | A |
| Example 53 | J-53 | R-1 | A |
| Example 54 | J-54 | R-1 | A |
| Comparative | CJ-1 | R-1 | C |
| Example 1 | | | |

### <Evaluation>

Using the compositions for forming a resist underlayer film prepared as described above, the rectangularity of a resist pattern was evaluated by the following method. The evaluation results are shown in Table 4.

### <Preparation of Resist Composition (R-2)>

### [Synthesis of Compound]

The compound (S-1) to be used for the preparation of a resist composition (R-2) was synthesized by the following procedure. In a reaction vessel, 6.5 parts by mass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 A molecular sieve, and then filtered through a filter having a pore size of 0.2 μm. Thus, a resist composition (R-2) was prepared.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation on which a 1:1 line-and-space resist pattern with a line width of 25 nm was formed. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 4

| | | | Resist pattern |
|---|---|---|---|
| | Composition | Resist composition | rectangularity |
| Example 1 | J-1 | R-2 | A |
| Example 2 | J-2 | R-2 | A |
| Example 3 | J-3 | R-2 | A |
| Example 4 | J-4 | R-2 | A |
| Example 5 | J-5 | R-2 | B |
| Example 6 | J-6 | R-2 | B |
| Example 7 | J-7 | R-2 | A |
| Example 8 | J-8 | R-2 | A |
| Example 9 | J-9 | R-2 | A |
| Example 10 | J-10 | R-2 | B |
| Example 11 | J-11 | R-2 | A |
| Example 12 | J-12 | R-2 | A |
| Example 13 | J-13 | R-2 | A |
| Example 14 | J-14 | R-2 | A |
| Example 15 | J-15 | R-2 | A |
| Example 16 | J-16 | R-2 | A |
| Example 17 | J-17 | R-2 | A |
| Example 18 | J-18 | R-2 | A |
| Example 19 | J-19 | R-2 | A |
| Example 20 | J-20 | R-2 | A |
| Example 21 | J-21 | R-2 | A |
| Example 22 | J-22 | R-2 | A |
| Example 23 | J-23 | R-2 | A |
| Example 24 | J-24 | R-2 | A |
| Example 25 | J-25 | R-2 | A |
| Example 26 | J-26 | R-2 | A |
| Example 27 | J-27 | R-2 | A |
| Example 28 | J-28 | R-2 | A |
| Example 29 | J-29 | R-2 | A |
| Example 30 | J-30 | R-2 | A |
| Example 31 | J-31 | R-2 | A |
| Example 32 | J-32 | R-2 | A |
| Example 33 | J-33 | R-2 | A |
| Example 34 | J-34 | R-2 | A |
| Example 35 | J-35 | R-2 | A |
| Example 36 | J-36 | R-2 | A |
| Example 37 | J-37 | R-2 | A |
| Example 38 | J-38 | R-2 | A |
| Example 39 | J-39 | R-2 | A |
| Example 40 | J-40 | R-2 | A |
| Example 41 | J-41 | R-2 | A |
| Example 42 | J-42 | R-2 | A |
| Example 43 | J-43 | R-2 | A |
| Example 44 | J-44 | R-2 | A |
| Example 45 | J-45 | R-2 | A |
| Example 46 | J-46 | R-2 | A |
| Example 47 | J-47 | R-2 | A |
| Example 48 | J-48 | R-2 | A |
| Example 49 | J-49 | R-2 | A |
| Example 50 | J-50 | R-2 | A |
| Example 51 | J-51 | R-2 | A |
| Example 52 | J-52 | R-2 | A |
| Example 53 | J-53 | R-2 | A |
| Example 54 | J-54 | R-2 | A |
| Comparative | CJ-1 | R-2 | C |
| Example 1 | | | |

As can be seen from the results shown in Tables 3 and 4, the resist underlayer films formed from the compositions for forming a resist underlayer film of Examples were superior in pattern rectangularity to the resist underlayer films formed from the compositions for forming a resist underlayer film of Comparative Examples.

According to the method for manufacturing a semiconductor substrate of the present disclosure, it is possible to efficiently manufacture a semiconductor substrate due to the use of a composition for forming a resist underlayer film capable of forming a resist underlayer film that can impart excellent pattern rectangularity to a resist pattern. According to the composition for forming a resist underlayer film of the present disclosure, it is possible to form a resist underlayer film that can impart excellent pattern rectangularity to a resist pattern. Therefore, they can suitably be used for, for example, manufacturing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a composition directly or indirectly to a substrate to form a resist underlayer film;
forming a resist film on the resist underlayer film;
exposing the resist film to radiation; and
developing the exposed resist film,
wherein the composition comprises:
a polymer; and
a solvent,
wherein the polymer comprises:
a repeating unit (1) comprising an organic sulfonic acid anion moiety and an onium cation moiety;
a repeating unit (2) represented by formula (2); and
a repeating unit (3) represented by formula (3): 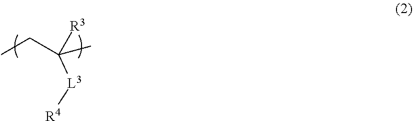
wherein in the formula (2), R³ is a hydrogen atom or a substituted or unsubstituted monovalent hydrocarbon group having 1 to 20 carbon atoms; L³ is a single bond or a divalent linking group; R⁴ is a group selected from the group consisting of groups represented by formulas (2-1) to (2-8), 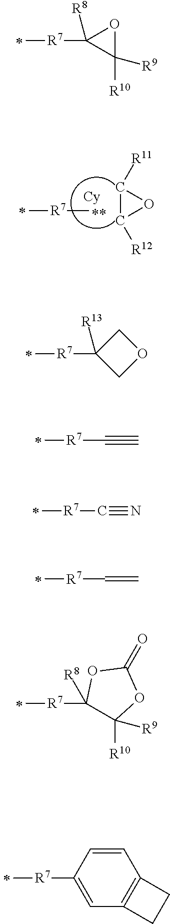
wherein in the formulas (2-1) to (2-3) and (2-7), R⁸, R⁹, R¹⁰, R¹², and R¹³ are each independently a hydrogen atom or a monovalent organic group having 1 to 20 carbon atoms; in the formula (2-2), Cy is a ring structure having 3 to 20 ring members constituted together with the two carbon atoms in the formula; R¹¹ is a hydrogen atom, a monovalent organic group having 1 to 20 carbon atoms, or a single bond; ** is a bond to an atom constituting Cy; provided that when R¹¹ is a single bond, R¹¹ is bonded to **; in the formulas (2-1) to (2-8), R⁷ is a divalent organic group having 1 to 20 carbon atoms or a single bond; * is a bond to an atom constituting L³, 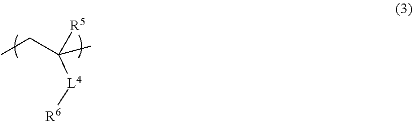
wherein in the formula (3), R⁵ is a hydrogen atom or a substituted or unsubstituted monovalent hydrocarbon group having 1 to 20 carbon atoms; L⁴ is a single bond or a divalent linking group; R⁶ is a group comprising a partial structure represented by formula (3-1) or (3-2), 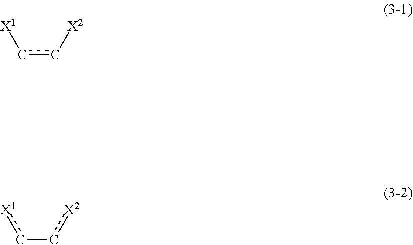
wherein in the formulas (3-1) and (3-2), X¹ and X² are each independently an oxygen atom, a sulfur atom, or a nitrogen atom; each [symbol]
independently represents a single bond or a double bond;
provided that the formula (3-1) is excluded from a definition of the formula (3-2).

2. The method according to claim 1, wherein the partial structure is represented by formula (3-1-1), (3-1-2), (3-1-3) or (3-2-1):

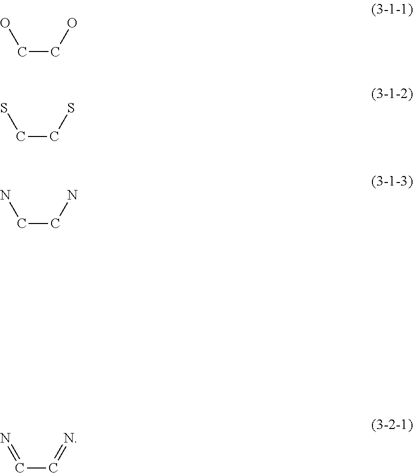

3. The method according to claim 1, wherein the repeating unit (1) is represented by formula (1-1) or (1-2), 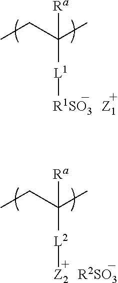
wherein in the formula (1-1), R^{a} is a hydrogen atom or a substituted or unsubstituted monovalent hydrocarbon group having 1 to 20 carbon atoms; L¹ is a divalent linking group; R¹ is a single bond or a divalent organic group having 1 to 40 carbon atoms; Z₁⁺ is a monovalent onium cation;
in the formula (1-2), R^{a} and L² are each defined as R^{a} and L¹ in the formula (1-1), respectively; Z₂⁺ is a monovalent group comprising a monovalent onium cation structure; R² is a monovalent organic group having 1 to 40 carbon atoms.

4. The method according to claim 3, wherein the repeating unit (1) is represented by the formula (1-1).

5. The method according to claim 1, wherein the resist film comprises a metal.

6. The method according to claim 5, wherein the resist film is formed from a composition for forming a metal-containing resist film; the composition for forming a metal-containing resist film comprises a metal-containing compound and a solvent; and a content ratio of the metal-containing compound in the composition to components other than the solvent in the composition is 50% by mass or more.

7. The method according to claim 1, wherein a content ratio of the repeating unit (1) in the polymer to all repeating units constituting the polymer is 1 mol % or more and 50 mol % or less.

8. The method according to claim 1, wherein a content ratio of the repeating unit (2) in the polymer to all repeating units constituting the polymer is 1 mol % or more and 80 mol % or less.

9. The method according to claim 1, wherein a content ratio of the repeating unit (3) in the polymer to all repeating units constituting the polymer is 1 mol % or more and 80 mol % or less.

10. The method according to claim 1, wherein the radiation is an electron beam or extreme ultraviolet rays.

11. A resist underlayer film forming composition comprising:
a polymer; and
a solvent,
wherein the polymer comprises:
a repeating unit (1) comprising an organic sulfonic acid anion moiety and an onium cation moiety;
a repeating unit (2) represented by formula (2); and
a repeating unit (3) represented by formula (3): 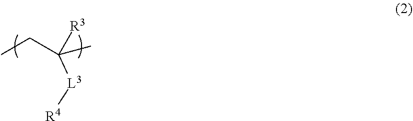
wherein in the formula (2), R³ is a hydrogen atom or a substituted or unsubstituted monovalent hydrocarbon group having 1 to 20 carbon atoms; L³ is a single bond or a divalent linking group; R⁴ is a group selected from the group consisting of groups represented by formulas (2-1) to (2-8), 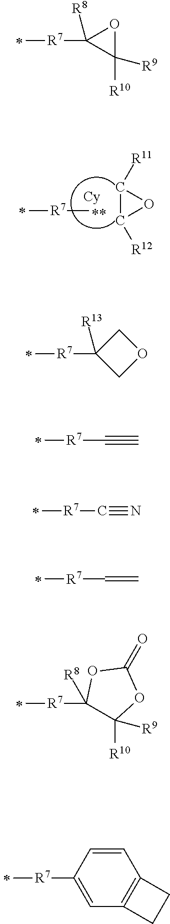
wherein in the formulas (2-1) to (2-3) and (2-7), R⁸, R⁹, R¹⁰, R¹², and R¹³ are each independently a hydrogen atom or a monovalent organic group having 1 to 20 carbon atoms; in the formula (2-2), Cy is a ring structure having 3 to 20 ring members constituted together with the two carbon atoms in the formula; R¹¹ is a hydrogen atom, a monovalent organic group having 1 to 20 carbon atoms, or a single bond; ** is a bond to an atom constituting Cy; provided that when R¹¹ is a single bond, R¹¹ is bonded to **; in the formulas (2-1) to (2-8), R⁷ is a divalent organic group having 1 to 20 carbon atoms or a single bond; * is a bond to an atom constituting L³, 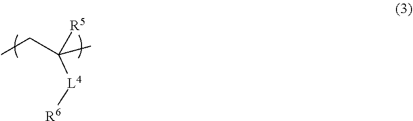
wherein in the formula (3), R⁵ is a hydrogen atom or a substituted or unsubstituted monovalent hydrocarbon group having 1 to 20 carbon atoms; L⁴ is a single bond or a divalent linking group; R⁶ is a group comprising a partial structure represented by formula (3-1) or (3-2), 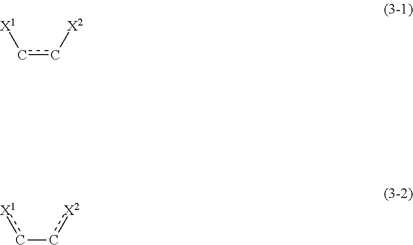
wherein in the formulas (3-1) and (3-2), X¹ and X² are each independently an oxygen atom, a sulfur atom, or a nitrogen atom; each [symbol]
independently represents a single bond or a double bond;
provided that the formula (3-1) is excluded from a definition of the formula (3-2).

12. The resist underlayer film forming composition according to claim 11, wherein the partial structure is represented by formula (3-1-1), (3-1-2), (3-1-3) or (3-2-1):

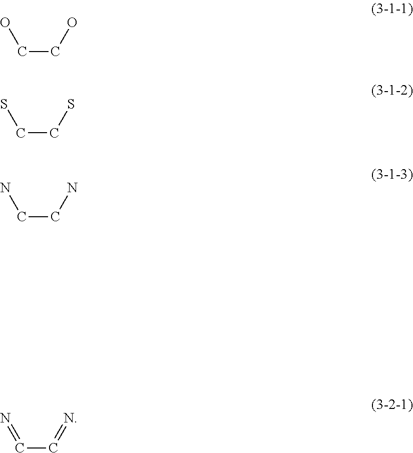

13. The resist underlayer film forming composition according to claim 11, wherein the repeating unit (1) is represented by formula (1-1) or (1-2): 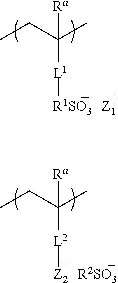
wherein in the formula (1-1), R^{a} is a hydrogen atom or a substituted or unsubstituted monovalent hydrocarbon group having 1 to 20 carbon atoms; L¹ is a divalent linking group; R¹ is a single bond or a divalent organic group having 1 to 40 carbon atoms; Z₁⁺ is a monovalent onium cation;
in the formula (1-2), R^{a} and L² are each defined as R^{a} and L¹ in the formula (1-1), respectively; Z₂⁺ is a monovalent group comprising a monovalent onium cation structure; R² is a monovalent organic group having 1 to 40 carbon atoms.

14. The resist underlayer film forming composition according to claim 13, wherein the repeating unit (1) is represented by the formula (1-1).

15. The resist underlayer film forming composition according to claim 11, wherein a content ratio of the repeating unit (1) in the polymer to all repeating units constituting the polymer is 1 mol % or more and 50 mol % or less.

16. The resist underlayer film forming composition according to claim 11, wherein a content ratio of the repeating unit (2) in the polymer to all repeating units constituting the polymer is 1 mol % or more and 80 mol % or less.

17. The resist underlayer film forming composition according to claim 11, wherein a content ratio of the repeating unit (3) in the polymer to all repeating units constituting the polymer is 1 mol % or more and 80 mol % or less.
